(19) United States
(12) Patent Application Publication
(10) Pub. No.: US 2026/0110077 A1
(43) Pub. Date: Apr. 23, 2026

(54) DEPOSITION APPARATUS

(71) Applicant: Samsung Display Co., LTD., Yongin-si (KR)

(72) Inventors: JEONGWON HAN, Yongin-si (KR); JAEWON SHIM, Yongin-si (KR); SUKWON JUNG, Yongin-si (KR)

(21) Appl. No.: 19/242,091

(22) Filed: Jun. 18, 2025

(30) Foreign Application Priority Data
Oct. 23, 2024 (KR) 10-2024-0145512

(51) Int. Cl. C23C 14/54; C23C 14/04; C23C 14/50

(52) U.S. Cl. CPC C23C 14/54; C23C 14/042; C23C 14/50

(57) ABSTRACT

A deposition apparatus includes a substrate chuck holder, a mask chuck, a first measurement unit, and a second measurement unit. A substrate chuck which fixes a substrate is disposed on the substrate chuck holder. The mask chuck fixes a mask defined with a plurality of openings. In a case in which the first measurement unit measures flatness of at least one of the substrate chuck or the substrate, the second measurement unit measures flatness of the mask. In a case in which the first measurement unit measures the flatness of the mask, the second measurement unit measures the flatness of at least one of the substrate chuck or the substrate. Accordingly, flatness of the substrate chuck, the mask and the substrate is measured with the deposition apparatus such that a more uniform deposition layer may be transferred on a substrate according to a shape of openings defined in the mask.

This application claims priority to Korean Patent Application No. 10-2024-0145512, filed on Oct. 23, 2024, and all the benefits accruing therefrom under 35 U.S.C. § 119, the content of which in its entirety is herein incorporated by reference.

### BACKGROUND

### 1. Field

The disclosure relates to a deposition apparatus. Particularly, the disclosure relates to a deposition apparatus for measurement of a substrate chuck, a mask and a substrate.

### 2. Description of the Related Art

A display panel of an electronic device may be manufactured through various processes. A deposition process may be used as one of the processes for manufacturing a display panel of an electronic device. The deposition process may be proceeded by depositing a deposition material on a substrate disposed on a substrate chuck. In some aspects, a mask having a specific pattern may be disposed on a plane of the substrate. The deposition material to be disposed on the substrate may have the specific pattern by the mask. The deposition process may be performed in a deposition chamber.

### SUMMARY

An object of the disclosure is to provide a deposition device for performing deposition to manufacture a display panel with a narrow pixel area and a high pixel density in a case in which flatness of a substrate chuck, a mask and a substrate is measured to satisfy a reference value.

A deposition device according to an embodiment of the disclosure may include a substrate chuck holder, a mask chuck, a guide, a guide transfer unit, a first measurement unit, and a second measurement unit. A substrate chuck which fixes a substrate may be disposed on the substrate chuck holder. The mask chuck may fix a mask defined with a plurality of openings. The mask chuck may be spaced apart from the substrate chuck holder. The guide may extend in a first direction parallel to a plane of the substrate chuck holder. The guide transfer unit may be disposed on the guide and move along with the guide in the first direction. The first measurement unit may include a first sensor. The first measurement unit may make contact with the guide transfer unit. The first measurement unit may extend in a second direction intersecting with the first direction. The second measurement unit may include a second sensor spaced apart from the first sensor. In a case in which flatness of at least one of the substrate chuck or the substrate is measured with the first measurement unit, flatness of the mask may be measured with the second measurement unit. In a case in which the flatness of the mask is measured with the first measurement unit, the flatness of at least one of the substrate chuck or the substrate may be measured with the second measurement unit.

In an embodiment of the disclosure, the second measurement unit may make contact with the guide transfer unit. In some aspects, the second measurement unit may extend in the second direction.

In an embodiment of the disclosure, the deposition apparatus may simultaneously measure flatness of the substrate chuck and flatness of the mask or simultaneously measure flatness of the substrate and flatness of the mask.

In an embodiment of the disclosure, the first measurement unit and the second measurement unit may overlap in a third direction orthogonal to the first direction and the second direction.

In an embodiment of the disclosure, the substrate chuck holder may be disposed above the first measurement unit. The mask chuck may be disposed below the second measurement unit. The first measurement unit may measure flatness of at least one of the substrate chuck or the substrate. The second measurement unit may measure flatness of the mask.

In an embodiment of the disclosure, the substrate chuck holder may be disposed above the first measurement unit. The mask chuck may be disposed above the second measurement unit. The first measurement unit may measure flatness of at least one of the substrate chuck or the substrate. The second measurement unit may measure flatness of the mask.

In an embodiment of the disclosure, the guide may include a first guide and a second guide. The second guide may be spaced apart from the first guide. The guide transfer unit may include a first guide transfer unit and a second guide transfer unit. The first guide transfer unit may be disposed on the first guide. The second guide transfer unit may be spaced apart from the first guide transfer unit and disposed on the second guide. The first measurement unit may make contact with the first guide transfer unit. The second measurement unit may make contact with the second guide transfer unit. The second measurement unit may extend in the second direction. The substrate chuck holder may be disposed above the first measurement unit. The mask chuck may be disposed below the second measurement unit. The first measurement unit may measure flatness of at least one of the substrate chuck or the substrate. The second measurement unit may measure flatness of the mask.

In an embodiment of the disclosure, the first measurement unit may measure flatness of the mask. The second measurement unit may measure flatness of at least one of the substrate chuck or the substrate. The substrate chuck holder may move in a direction parallel to a plane defined by the first direction and the second direction. While the second measurement unit measures the flatness of at least one of the substrate chuck or the substrate, the second measurement unit may not overlap with the mask chuck in a third direction orthogonal to the first direction and the second direction.

In an embodiment of the disclosure, a chamber may be further included. The chamber may include a transparent member. The transparent member may overlap with the second measurement unit in the third direction. The chamber may accommodate the substrate chuck holder, the mask chuck, the guide, the guide transfer unit, and the first measurement unit inside the chamber. The second measurement unit may be disposed outside of the chamber.

In an embodiment of the disclosure, the first measurement unit may measure flatness of at least one of the substrate chuck or the substrate. The second measurement unit may measure flatness of the mask. The mask chuck may move in a direction parallel to a plane defined by the first direction and the second direction. While the second measurement unit measures the flatness of the mask, the second measurement unit may not overlap with the substrate chuck holder in a third direction orthogonal to the first direction and the second direction.

In an embodiment of the disclosure, a chamber may be further included. The chamber may include a transparent member. The transparent member may overlap with the second measurement unit in the third direction. The chamber may accommodate the substrate chuck holder, the mask chuck, the guide, the guide transfer unit, and the first measurement unit inside the chamber. The second measurement unit may be disposed outside of the chamber.

In an embodiment of the disclosure, a controller may be further included. The controller may be configured to control the substrate chuck to fix the substrate in a case in which the flatness of the substrate chuck is greater than or equal to a selectable substrate chuck reference value. The controller may proceed with a deposition process when the flatness of the mask is greater than or equal to a selectable mask reference value and the flatness of the substrate is greater than or equal to a selectable substrate reference value.

In an embodiment of the disclosure, the controller may control the substrate chuck to fix the substrate when the flatness of the substrate chuck is greater than or equal to a selectable substrate chuck reference value and the flatness of the mask is greater than or equal to a selectable mask reference value.

A deposition apparatus according to an embodiment of the disclosure may include a substrate chuck holder, a mask chuck, a guide, a guide transfer unit, and a measurement unit. A substrate chuck configured to fix a substrate may be disposed on the substrate chuck holder. The mask chuck may fix a mask defined with a plurality of openings. In some aspects, the mask chuck may be spaced apart from the substrate chuck holder. The guide may extend in a first direction parallel to a plane of the substrate chuck holder. The guide transfer unit may be disposed on the guide and move along with the guide in the first direction. The measurement unit may include a sensor. In some aspects, the measurement unit may make contact with the guide transfer unit. The measurement unit may extend in a second direction intersecting with the first direction. In some aspects, the measurement unit may have an upper mode, in which the sensor is positioned at a first height. In some aspects, the measurement unit may have a lower mode, in which the sensor is positioned at a second height lower than the first height. The measurement unit may measure flatness of at least one of the substrate chuck or the substrate under the upper mode. In some aspects, the measurement unit may measure flatness of the mask under the lower mode.

In an embodiment of the disclosure, the substrate chuck holder may be disposed at a position higher than the first height. The mask chuck may be disposed at a position lower than the second height.

In an embodiment of the disclosure, the substrate chuck holder may be disposed at a position higher than the first height. The mask chuck may be disposed at a position lower than the first height and higher than the second height.

In an embodiment of the disclosure, the guide may include a first guide and a second guide. The second guide may be disposed at a position lower than the first guide. The measurement unit may make contact with the first guide under the upper mode. In some aspects, the measurement unit may make contact with the second guide under the lower mode.

In an embodiment of the disclosure, a controller may be further included. The controller may control the substrate chuck to fix the substrate in a case in which the flatness of the substrate chuck is greater than or equal to a selectable substrate chuck reference value. The controller may proceed with a deposition process in a case in which the flatness of the mask is greater than or equal to a selectable mask reference value and the flatness of the substrate is greater than or equal to a selectable substrate reference value.

A deposition apparatus according to an embodiment of the disclosure may include a substrate chuck holder, a mask chuck, a chamber, and a measurement unit. A substrate chuck configured to fix a substrate may be disposed on the substrate chuck holder. The mask chuck may fix a mask defined with a plurality of openings. In some aspects, the mask chuck may be spaced apart from the substrate chuck holder. The chamber may include a transparent member. In some aspects, the chamber may accommodate the substrate chuck holder and the mask chuck inside of the chamber. The measurement unit may include a sensor. In some aspects, the measurement unit may overlap with the transparent member. The measurement unit may be disposed outside of the chamber. The substrate chuck holder and the mask chuck may move in a direction parallel to a plane where the substrate chuck is disposed. While the measurement unit overlaps with the substrate chuck holder and not with the mask chuck, the measurement unit may measure flatness of at least one of the substrate chuck or the substrate. In some aspects, while the measurement unit overlaps with the mask chuck, the measurement unit may measure flatness of the mask.

In an embodiment of the disclosure, a controller may be further included. The controller may control the substrate chuck to fix the substrate in a case in which the flatness of the substrate chuck is greater than or equal to a selectable substrate chuck reference value. The controller may proceed with controlling a deposition process in a case in which the flatness of the mask is greater than or equal to a selectable mask reference value and the flatness of the substrate is greater than or equal to a selectable substrate reference value.

Embodiments of the present disclosure support measuring flatness of a substrate chuck, a mask, and a substrate. Accordingly, embodiments of the present disclosure support performing a deposition process after confirmation that the flatness of a substrate chuck, a mask, and a substrate satisfies a reference value. Therefore, embodiments of the present disclosure support reducing a defectiveness percentage of a deposition process. Furthermore, embodiments of the present disclosure support providing a deposition apparatus for manufacture of a display panel with a narrow pixel area and a high pixel density.

### BRIEF DESCRIPTION OF THE DRAWINGS

These and/or other features will become apparent and more readily appreciated from the following description of the embodiments, taken in conjunction with the accompanying drawings in which:

FIG. 1A is an example front view of a deposition apparatus according to an embodiment of the disclosure;

FIG. 1B is a magnified view of the AA section illustrated in FIG. 1A;

FIG. 1C is an example side view of a deposition apparatus according to an embodiment of the disclosure;

FIG. 1D is an example top view of a deposition apparatus according to an embodiment of the disclosure;

FIG. 1E is an example perspective view of a deposition apparatus according to an embodiment of the disclosure;

FIG. 1F is an example side view of a deposition apparatus having a substrate chuck and a mask disposed according to an embodiment of the disclosure;

FIG. 1G is an example side view of a deposition apparatus having a substrate chuck, a mask and a substrate disposed according to an embodiment of the disclosure;

FIG. 2 is an example flow diagram of a method of operating a deposition apparatus according to an embodiment of the disclosure;

FIGS. 3A, 3B, 3C, and 3D are each a schematic side view of a deposition apparatus in a step of an operation method according to an embodiment of the disclosure;

FIG. 4 is an example top view of a substrate according to an embodiment of the disclosure;

FIG. 5 is an example cross-sectional view of a display panel manufactured according to an embodiment of the disclosure;

FIG. 6A is an example front view of a deposition apparatus according to an embodiment of the disclosure;

FIG. 6B is an example side view of a deposition apparatus according to an embodiment of the disclosure;

FIG. 7A is an example front view of a deposition apparatus according to an embodiment of the disclosure;

FIG. 7B is an example side view of a deposition apparatus according to an embodiment of the disclosure;

FIGS. 8A, 8B, and 8C are example side views of a deposition apparatus according to an embodiment of the disclosure;

FIG. 9 is an example side view of a deposition apparatus according to an embodiment of the disclosure;

FIGS. 10A and 10B are example side views of a deposition apparatus according to an embodiment of the disclosure;

FIG. 11A is an example front view of a deposition apparatus according to an embodiment of the disclosure;

FIGS. 11B, 11C, and 11D are example side views of a deposition apparatus according to an embodiment of the disclosure;

FIGS. 12A and 12C are examples front views of a deposition apparatus according to an embodiment of the disclosure;

FIGS. 12B and 12D are example side views of a deposition apparatus according to an embodiment of the disclosure;

FIGS. 13A and 13B are examples front views of a deposition apparatus according to an embodiment of the disclosure; and

FIGS. 14A, 14B, and 14C are example side views of a deposition apparatus according to an embodiment of the disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are described herein, by referring to the figures, to explain features of the disclosure.

In the accompanying drawings, ratios and dimensions of the elements may not be to exact scale and may have been exaggerated for the benefit of effective explanation of the technical features associated with these elements. Any reference to “and/or” shall be construed to include one or more combinations that can be defined by relevant elements.

When a device or a layer is “above” another device or layer, the device or the layer may be right above the other device or layer or have yet another device or layer interposed in the middle. When a device is “right above” another device, yet another device or layer is not interposed in the middle. A same reference numeral is used for the same element over the description.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

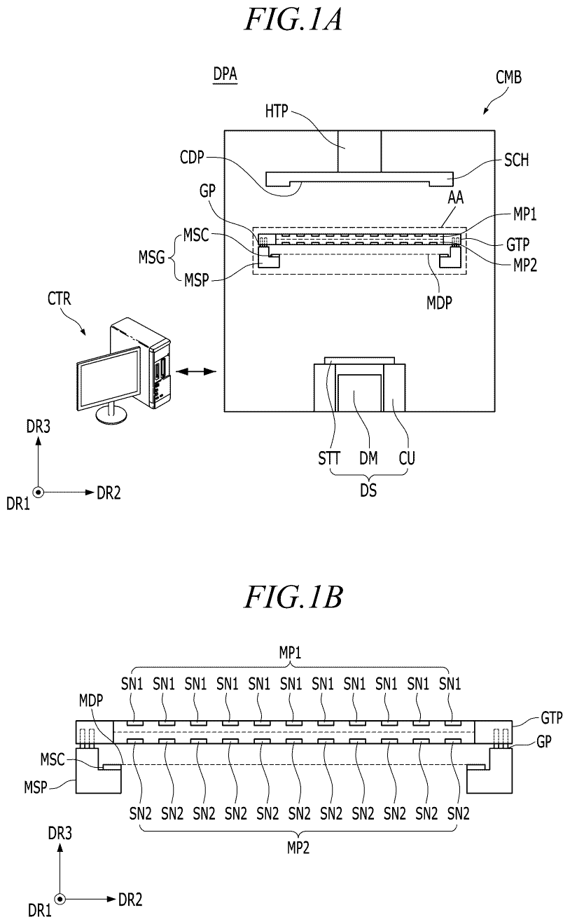

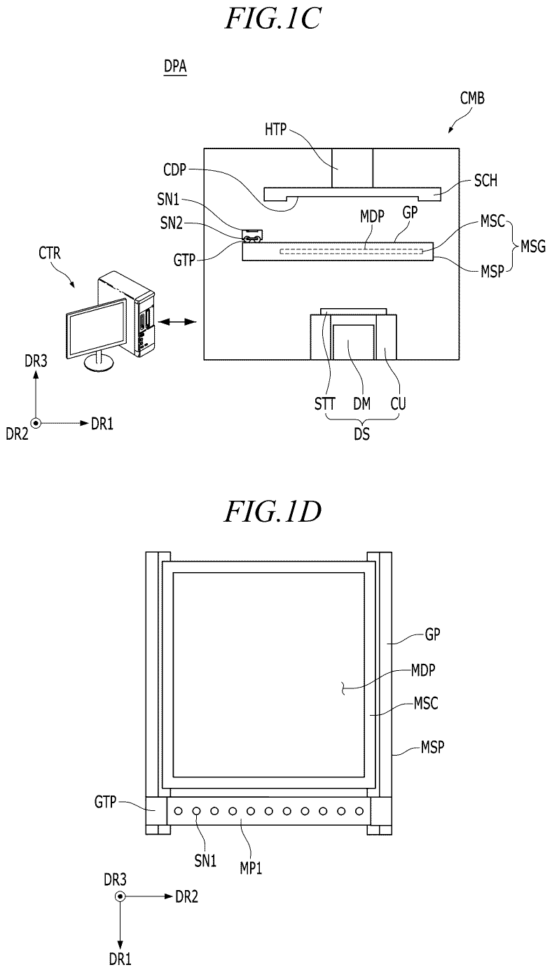

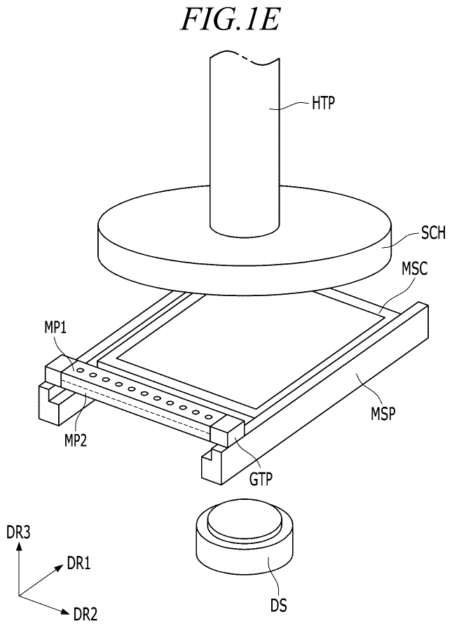

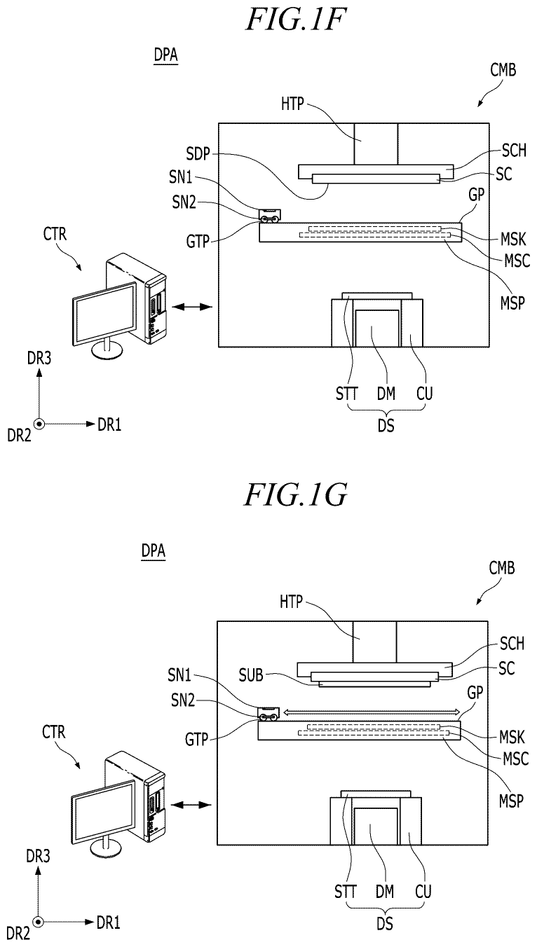

FIG. 1A is an example front view of a deposition apparatus DPA according to an embodiment of the disclosure. FIG. 1B is a magnified view of the AA section illustrated in FIG. 1A. FIG. 1C is an example side view of a deposition apparatus DPA according to an embodiment of the disclosure. FIG. 1D is an example top view of a deposition apparatus DPA according to an embodiment of the disclosure. FIG. 1E is an example perspective view of a deposition apparatus DPA according to an embodiment of the disclosure. FIG. 1F is an example side view of a deposition apparatus DPA having a substrate chuck SC and a mask MSK disposed according to an embodiment of the disclosure. FIG. 1G is an example side view of a deposition apparatus DPA having a substrate chuck SC, a mask MSK and a substrate SUB disposed according to an embodiment of the disclosure.

Referring to FIGS. 1A, 1B, 1C, 1D, 1E, 1F, and 1G, a deposition apparatus DPA may include a chamber CMB, a holder transfer unit HTP, a substrate chuck holder SCH, a mask stage MSG, a guide GP, a guide transfer unit GTP, a first measurement unit MP1, a second measurement unit MP2, a deposition source DS, and a controller CTR. Some elements are omitted in FIGS. 1B, 1D and 1E. In some aspects, a substrate chuck SC and a mask MSK are disposed on the deposition apparatus DPA in FIG. 1F, and a substrate chuck SC, a mask MSK, and a substrate SUB are disposed on the deposition apparatus DPA in FIG. 1G.

Referring to FIG. 1A, and 1C, the chamber CMB may have an inner space, a bottom plane and a ceiling plane. In some aspects, a deposition process on a substrate SUB may be performed inside the chamber CMB.

The inner space may be defined as a space inside the chamber CMB. The chamber CMB may be configured to accommodate a holder transfer unit HTP, a substrate chuck holder SCH, a mask stage MSG, a guide GP, a guide transfer unit GTP, a first measurement unit MP1, a second measurement unit MP2, and a deposition source DS. An element accommodated by the chamber CMB may be disposed in the inner space.

A pressure of the inner space may be controlled. For example, a pressure of the inner space may be decreased. The inner space may be in a vacuum state. The inner space may be in a vacuum state such that a deposition process performed by the deposition apparatus DPA may be more uniformly performed and efficiency may increase.

The bottom plane may be defined as a lowest plane among inside planes or a plane where the deposition source DS is disposed. The bottom plane may be parallel to a plane defined by a first directional axis DR1 and a second directional axis DR2. A direction of a height of the chamber CMB may be directed by a third directional axis DR3. An upper direction and a lower direction of each member may be distinguished by the third directional axis DR3. However, directions pointed by the first through the third directional axes are a relative concept and may be converted into other directions. Hereinafter, the first through the third directions DR1, DR2 and DR3 are directions pointed by the first through the third directional axes DR1, DR2 and DR3, respectively, and described with the same figure references.

The ceiling plane may be defined as a plane most spaced apart from the bottom plane among the inner planes. The ceiling plane may be parallel to a plane defined by the first directional axis DR1 and the second directional axis DR2.

The holder transfer unit HTP may extend in the third direction DR3 to make contact with the substrate chuck holder SCH. The holder transfer unit HTP may move in the third direction DR3 and be configured to move the substrate chuck holder SCH in the third direction DR3.

In some aspects, the holder transfer unit HTP may be configured to move in the first direction DR1 and the second direction DR2. For example, the holder transfer unit HTP may move in a direction parallel to the bottom plane and the ceiling plane.

The holder transfer unit HTP may be disposed in a plurality. The plurality of holder transfer units HTP may make contact with the substrate chuck holder SCH at different places and be controlled to have different lengths from one another. Accordingly, the substrate chuck holder SCH may be inclined by the plurality of holder transfer units HTP. For example, number of the plurality of holder transfer units HTP may be 6, and the six holder transfer units HTP may form a hexapod.

Referring to FIGS. 1A, 1C, 1F and 1G, a substrate chuck SC may be disposed on the substrate chuck holder SCH. In some aspects, a substrate chuck disposition plane CDP may be defined as a plane where the substrate chuck SC is disposed on a substrate chuck holder SCH. The substrate chuck disposition plane CDP may be a plane facing downwards among planes composing a substrate chuck holder SCH. In some aspects, the substrate chuck disposition plane CDP may be parallel to the bottom plane.

A substrate chuck SC may be disposed on the substrate chuck holder SCH. A substrate chuck disposition plane CDP may be defined as a plane where the substrate chuck SC is disposed on a substrate chuck holder SCH.

A substrate SUB may be disposed on the substrate chuck SC. A substrate disposition plane SDP may be defined as a plane where a substrate SUB is disposed on the substrate chuck SC. In some aspects, the substrate chuck SC may be configured to fix the substrate SUB disposed on the substrate disposition plane SDP.

Flatness of the substrate chuck SC may affect performance of the substrate chuck SC fixing the substrate SUB. For example, in a case in which the flatness of the substrate chuck SC is greater than or equal to a selectable substrate chuck reference value, the substrate chuck SC may properly fix the substrate SUB. However, in a case in which the flatness of the substrate chuck SC is less than a selectable substrate chuck reference value, the substrate chuck SC may not properly fix the substrate SUB. Furthermore, in a case in which the substrate chuck SC does not properly fix the substrate SUB, the substrate SUB may be separated from the substrate chuck SC. Eventually, a deposition process on the substrate SUB may not be performed, and the substrate SUB may be damaged.

Flatness of the substrate chuck SC may affect a deposition process. For example, in a case in which the flatness of the substrate chuck SC is greater than or equal to a selectable substrate chuck reference value, a thickness of a deposition layer manufactured through a deposition process may be uniform. However, in a case in which the flatness of the substrate chuck SC is less than a selectable substrate chuck reference value, a thickness of a deposition layer manufactured through a deposition process may not be uniform. Furthermore, in a case in which a thickness of a deposition layer is not uniform, the deposition layer may not function properly.

In a case in which the flatness of the substrate chuck SC is less than a selectable substrate chuck reference value, an action may be taken to increase flatness of the substrate chuck SC. For example, the substrate chuck SC may be replaced with another substrate chuck SC. In another embodiment, a separate device may be further disposed for increasing flatness of the substrate chuck SC such that the flatness of the substrate chuck SC may be improved through operation of the separate device. For example, the substrate chuck SC may be pulled by the separate device to opposite sides on a plane including a substrate chuck disposition plane CDP. Accordingly, flatness of a substrate chuck SC may be improved.

The substrate chuck SC may include an electrostatic chuck. After disposition of a substrate SUB on a substrate disposition plane SDP, voltage may be applied to the electrostatic chuck such that the substrate chuck SC and the substrate SUB may be induced with a different type of charge from each other. Accordingly, an electrostatic attraction may be induced between the substrate chuck SC and the substrate SUB to fix the substrate SUB on the substrate chuck SC.

An element of the substrate chuck SC is not limited to the above. The substrate chuck SC may include one of a vacuum chuck, a mechanical chuck, a magnetic chuck, a pogo pin chuck, a gas static pressure chuck, or a thermal chuck. Other than the above, any device configured to fix a substrate SUB may be included in a substrate chuck SC.

A substrate may be a subject for operation of a deposition process. In some aspects, after the deposition process, a new deposition layer may be formed on the substrate SUB. The substrate SUB may include a semiconductor wafer. Particularly, the substrate SUB may include, for example, a silicon wafer, a composition semiconductor wafer, a silicon carbide wafer, a sapphire wafer, or a diamond wafer. An electron movement speed may be fast on the substrate SUB because the substrate SUB includes a semiconductor wafer.

In a case in which an electron movement speed is fast on a substrate SUB, a micro display may be manufactured with the substrate SUB. For example, a display panel including OLEDoS (OLED on Silicon), LEDoS (LED on Silicon), or LCoS (Liquid Crystal on Silicon) may be manufactured with the substrate SUB. However, a device to be manufactured with the substrate SUB is not limited to the above. A display device including at least one of OLED or QLED may be manufactured with the substrate SUB. In some aspects, a device, such as, for example, a calculation device or a storage device, may be manufactured with the substrate SUB.

In some aspects, the substrate SUB may include an organic layer and/or an inorganic layer. The organic layer may include an organic material. For example, the organic layer may include polyimide. The inorganic layer may include an inorganic material. For example, the inorganic layer may include glass. In some aspects, a plurality of organic layers and a plurality of inorganic layers may be alternately disposed to form the substrate SUB.

Flatness of a substrate SUB may affect a deposition process. For example, in a case in which the flatness of a substrate SUB is greater than or equal to a selectable substrate reference value, a thickness of a deposition layer manufactured through the deposition process may be uniform. However, in a case in which the flatness of a substrate SUB is less than a selectable substrate reference value, a thickness of a deposition layer manufactured through the deposition process may not be uniform. In some aspects, in a case in which a thickness of a deposition layer is not uniform, the deposition layer may not properly function.

In a case in which the flatness of a substrate SUB is less than a selectable substrate reference value, an action may be taken to increase flatness of a substrate SUB. For example, the substrate SUB may be replaced with another substrate SUB. In another embodiment, a separate device for increasing flatness of a substrate SUB may be further disposed such that the flatness of a substrate SUB may be improved through operation of the device. For example, a substrate SUB may be pulled by the separate device to opposite sides on a plane including a substrate disposition plane SDP. Accordingly, flatness of the substrate SUB may be improved.

Referring to FIGS. 1A, 1D, and 1F, the mask stage MSG may include a mask support MSP, and a mask chuck MSC. In some aspects, a mask disposition plane MDP, where a mask MSK is disposed, may be defined on the mask stage MSG. The mask stage MSG may be spaced apart from the substrate chuck holder SCH.

The mask support MSP may be configured to support the mask chuck MSC and the mask MSK.

The mask chuck MSC may be disposed on the mask support MSP. The mask MSK may be disposed on the mask chuck MSC. A mask disposition plane MDP, where the mask MSK is disposed, may be defined on the mask chuck MSC. The mask chuck MSC may be configured to fix the mask MSK disposed on the mask disposition plane MDP. The mask chuck MSC may be spaced apart from the substrate chuck holder SCH.

The mask chuck MSC may include an electrostatic chuck. The mask MSK disposed on the mask chuck MSC may be fixed to the mask chuck MSC by an electrostatic attraction.

However, an element of the mask chuck MSC is not limited to the above. The mask chuck MSC may include at least one of a vacuum chuck, a mechanical chuck, a magnetic chuck, a pogo pin chuck, a gas static pressure chuck, or a thermal chuck. Other than above, any device configured to fix a mask MSK may be included in the mask chuck MSC.

The mask chuck MSC may be configured to support a portion of the mask MSK. In some aspects, the other portion of the mask MSK may not be supported by the mask chuck MSC such that the mask MSK may be inclined downwards. Therefore, the mask MSK may not be flat.

The mask MSK may include a plurality of openings having a consistent pattern. Therefore, a deposition layer manufactured on a substrate during a deposition process on a substrate SUB may be transferred according to a shape of the plurality of openings defined on the mask MSK.

Flatness of a mask MSK may affect a deposition process. For example, in a case in which the flatness of a mask MSK is greater than or equal to a selectable mask reference value, a deposition layer formed on a substrate SUB through a deposition process may be properly transferred according to a shape of a plurality of openings defined in the mask MSK. However, in a case in which the flatness of a mask MSK is less than a selectable mask reference value, a deposition layer formed on a substrate SUB through a deposition process may not be properly transferred according to a shape of a plurality of openings defined in the mask MSK. In a case in which a deposition layer is not properly transferred, the deposition layer may not function properly.

In a case in which the flatness of a mask MSK is less than a selectable mask reference value, an action may be taken to increase flatness of the mask MSK. For example, the mask MSK may be washed or replaced. In another embodiment, a separate device for increasing flatness of a mask MSK may be further disposed such that the flatness of the mask MSK may be improved through operation of the separate device. For example, a magnet may be disposed on the mask MSK such that a portion of the mask MSK, which is not supported by the mask chuck MSC, may be lifted. In another embodiment, a support may be disposed below the mask MSK such that a portion of the mask MSK, which is not supported by the mask chuck MSC, may be lifted.

Referring to FIGS. 1C, 1D, and 1E, the guide GP may be defined on the mask support unit MSP and extend in a direction parallel to the substrate chuck disposition plane CDP. For example, the guide GP may extend in the first direction DR1. The guide GP may include a rail. In some aspects, a roller may be disposed on the guide GP and move along with the guide GP in the first direction DR1.

However, a position of the guide GP is not limited to what is described in the above embodiment. In an embodiment of the disclosure, the guide GP may be disposed below the mask support unit MSP. Furthermore, in yet another embodiment, the guide GP may be positioned on a separate member other than the mask stage MSG.

In some aspects, an element of the guide GP is not limited to what is described herein. In a case in which there is any component providing a path and any device moving along the path, the component providing a path may be included in the guide GP.

The guide GP may include a guide rail. The guide rail may be a rail including a concavo-convex portion. In some aspects, a guide roller having a concavo-convex shape corresponding to the concavo-convex portion of the guide rail may move along the guide rail.

The guide GP may include a magnetic levitation track. The magnetic levitation track may provide a path based on a principle of electromagnetism, and a magnetic levitation transfer unit may move along the magnetic levitation track.

The guide GP may include a linear motion guide LM Guide. The linear motion guide may provide a linear path, and a linear motion block LM Block may move along with the linear motion guide.

In some aspects, the guide GP may be disposed in a plurality. For example, the plurality of guides GP may be arranged parallel to the second direction DR2.

A guide transfer unit GTP may be disposed on the guide GP. In some aspects, the guide transfer unit GTP may move along with the guide GP in a direction of extension of the guide. The guide transfer unit GTP may include at least one of a roller, a guide roller, a magnetic levitation transfer unit, or a linear motion block according to a configuration of the guide GP.

In some aspects, an element of the guide transfer unit GTP is not limited to what is described in the above embodiment. If there is any component providing a path and any device moving along the path, the device moving along the path may be included in the guide transfer unit GTP.

The first measurement unit MP1 may include a first sensor SN1. In some aspects, the first measurement unit MP1 may make contact with the guide transfer unit GTP and move along with the guide transfer unit GTP in the first direction DR1.

The first measurement unit MP1 may extend in the second direction DR2. The first measurement unit MP1 may be disposed below the substrate chuck holder SCH and above the mask chuck MSC.

The first measurement unit MP1 may be configured to measure flatness of a facing component. The first measurement unit MP1 may face above. In some aspects, a subject of which flatness is measured by the first measurement unit MP1 may be defined as a first measurement subject. For example, in a case in which the first measurement unit MP1 faces the substrate chuck SC, flatness of the substrate chuck SC may be measured. In a case in which the first measurement unit MP1 faces the substrate SUB, flatness of the substrate SUB may be measured. In some aspects, the substrate chuck SC and the substrate SUB may be defined as the first measurement subject. However, the above descriptions are examples, and in another embodiment, a mask MSK may be defined as a first measurement subject.

The first sensor SN1 may be a non-contact displacement sensor. The first sensor SN1 may be configured to measure a distance from the first measurement subject.

The first sensor SN1 may include at least one of a confocal displacement sensor, a laser displacement sensor, a capacitance sensor, an Eddy-current sensor, or a coordinate measuring machine with auto focusing sensor. However, an element of the first sensor SN1 is not limited to the above examples. Other than the above, any sensor configured to measure a displacement of an object or a distance between a sensor and an object may be included in the first sensor SN1.

The first sensor SN1 may be disposed in a plurality. The plurality of the first sensors SN1 may be arranged in the second direction DR2. In some aspects, the plurality of first sensors SN1 may move along with the guide transfer unit GTP in the first direction DR1. While the plurality of first sensors SN1 move in the first direction DR1, a distance between the plurality of first sensors SN1 and the first measurement subject may be measured such that the flatness of the first measurement subject is measured. In other words, the first measurement subject may be scanned by the first sensors SN1 such that the flatness of the first measurement subject is measured.

The second measurement unit MP2 may include a second sensor SN2. In some aspects, the second measurement unit MP2 may make contact with the guide transfer unit GTP and move along with the guide transfer unit GTP in the first direction DR1.

The second measurement unit MP2 may extend in the second direction DR2. The second measurement unit MP2 may be disposed below the substrate chuck holder SCH and above the mask chuck MSC.

The second measurement unit MP2 may be configured to measure flatness of a facing component. The second measurement unit MP2 may face downwards. In some aspects, a subject of which flatness is measured by the second measurement unit MP2 may be defined as a second measurement subject. For example, in a case in which the second measurement unit MP2 faces a mask MSK, flatness of the mask MSK may be measured. Accordingly, the mask MSK may be defined as a second measurement subject. However, the above description is an example, and in another embodiment, a substrate chuck SC and a substrate SUB may be defined as a second measurement subject.

The second sensor SN2 may be a non-contact displacement sensor. The second sensor SN2 may be configured to measure a distance from the second measurement subject.

The second sensor SN2 may have the same configuration as the first sensor SN1 other than a direction, a position, and a measurement subject. In some aspects, the second sensor SN2 may be disposed in a plurality. A method of measuring the flatness of the second measurement subject with the plurality of second sensors SN2 may be the same as the method of measuring the flatness of the first measurement subject with the plurality of first sensors SN1.

The first measurement unit MP1 and the second measurement unit MP2 may operate simultaneously. Particularly, while the guide transfer unit GTP moves in the first direction DR1, the first sensor SN1 may measure flatness of the first measurement subject, and the second sensor SN2 may measure flatness of the second measurement subject. Accordingly, the first measurement unit MP1 and the second measurement unit MP2 may simultaneously measure flatness of the first measurement subject and flatness of the second measurement subject. As the result, the simultaneous measuring may reduce time for measuring the flatness of the substrate chuck SC, the mask MSK, and the substrate SUB.

Referring FIGS. 1A and 1C, the deposition source DS may include a crucible CU, a deposition material DM, and an opening and closing part STT. In some aspects, the deposition source DS may release a deposition material DM. The deposition source DS may be disposed on a bottom surface.

The crucible CU may be configured to accommodate the deposition material DM. The crucible CU may be disposed on the bottom surface. In some aspects, the crucible CU may be heated to be prepared for a deposition process.

The deposition material DM may be heated via the crucible CU. In some aspects, the deposition material DM may be evaporated by the heat. The evaporated deposition material DM may be deposited on the substrate SUB to form a deposition layer, and a deposition process may be performed.

In some aspects, a portion of the deposition material DM may be deposited on the mask MSK. In a case in which the deposition material DM is deposited on the mask MSK, performance of the mask MSK may be adversely affected. For example, a deposition layer deposited on the substrate SUB may not be properly transferred according to a shape of the plurality of openings defined in the mask MSK. Therefore, the mask MSK may be periodically washed or replaced to remove the deposition material DM deposited on the mask MSK.

The opening and closing part STT may be disposed on the crucible CU to be open or closed. In a case in which the opening and closing part STT is open, the deposition material DM evaporated in the crucible CU may be released towards above such that a deposition process proceeds. However, in a case in which the opening and closing part STT closes, the deposition material DM evaporated in the crucible CU may not be released towards above such that a deposition process does not proceed.

A controller CTR may be disposed inside or outside of the chamber CMB. The controller CTR may be configured to control operation of the deposition apparatus DPA. For example, the controller CTR may be configured to dispose the substrate chuck SC on the substrate chuck disposition plane CDP, the substrate SUB on the substrate disposition plane SDP, and the mask MSK on the mask disposition plane MDP. The controller CTR may be configured to have the deposition material DM released towards above from the deposition source DS. In some aspects, the controller CTR may be configured to control the substrate chuck SC to fix the substrate SUB and the mask chuck MSC to fix the mask MSK. The controller CTR may be, for example, a computing device, a controller circuit, or the like.

The controller CTR may be configured to control the first measurement unit MP1 to measure flatness of the substrate chuck SC and flatness of the substrate SUB. In some aspects, the controller CTR may be configured to control the second measurement unit MP2 to measure flatness of the mask MSK.

The controller CTR may be configured to set a period for measuring the flatness of the substrate chuck SC, flatness of the substrate SUB, and flatness of the mask MSK. For example, the controller CTR may be configured to have flatness of a substrate chuck SC measured each time before a deposition process is to be performed, each time a selectable number of a deposition process has been performed, or each time a substrate chuck SC is replaced. In some aspects, the controller CTR may be configured to have flatness of a substrate SUB measured each time before a deposition process to be performed, or each time a selectable number of deposition process has been performed. The controller CTR may be configured to have flatness of a mask MSK measured each time before a deposition process is to be performed, each time a selectable number of deposition process has been performed, or each time a mask MSK is washed or replaced.

The controller CTR may be configured to replace a substrate chuck SC, a substrate SUB, or a mask MSK based on a measured value of flatness of the substrate chuck SC, flatness of the substrate SUB, and flatness of the mask MSK. For example, in a case in which the flatness of a substrate chuck SC is determined to be less than a substrate chuck reference value by the controller CTR, the controller CTR may replace the substrate chuck SC or operate a separate device for improving flatness of the substrate chuck SC. In some aspects, in a case in which the flatness of a substrate SUB is determined to be less than a substrate reference value by the controller CTR, the controller CTR may replace the substrate SUB or operate a separate device for improving flatness of the substrate SUB. In some aspects, in a case in which the flatness of a mask MSK is less than a mask reference value by the controller CTR, the controller CTR may replace the mask MSK or operate a separate device for improving flatness of the mask MSK.

The controller CTR may be configured to identify damage of a substrate chuck SC, a substrate SUB, and a mask MSK. The controller CTR may be configured to have a damaged component replaced.

In a case in which the flatness of a substrate chuck SC is greater than or equal to a selectable substrate chuck reference value and flatness of a mask MSK is greater than or equal to a selectable mask reference value, the controller CTR may be configured to have a substrate SUB disposed on the substrate chuck SC. In a case in which a substrate SUB is disposed on a substrate chuck SC and flatness of the substrate SUB is greater than or equal to a selectable substrate reference value, the controller CTR may have a deposition material DM released towards above from a deposition source DS.

However, a controlling method of the controller CTR is not limited to the above. For example, in a case in which the flatness of a substrate chuck SC is greater than or equal to a selectable substrate chuck reference value, the controller CTR may have a substrate SUB disposed on a substrate chuck SC. In a case in which a substrate SUB is disposed on a substrate chuck SC, flatness of the substrate SUB is greater than or equal to a selectable substrate reference value, and flatness of a mask MSK is greater than or equal to a selectable mask reference value, the controller CTR may have a deposition material DM released towards above from a deposition source DS.

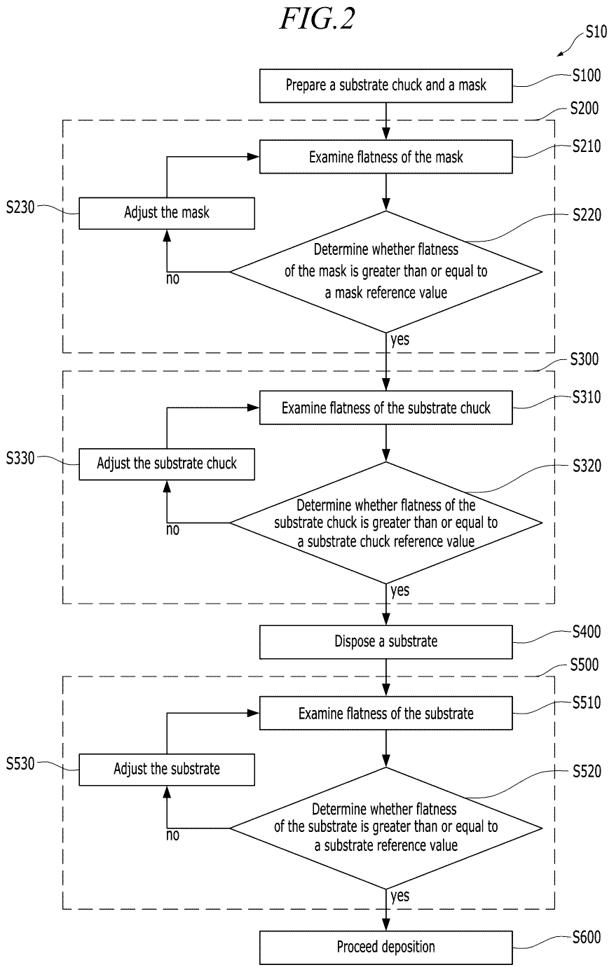

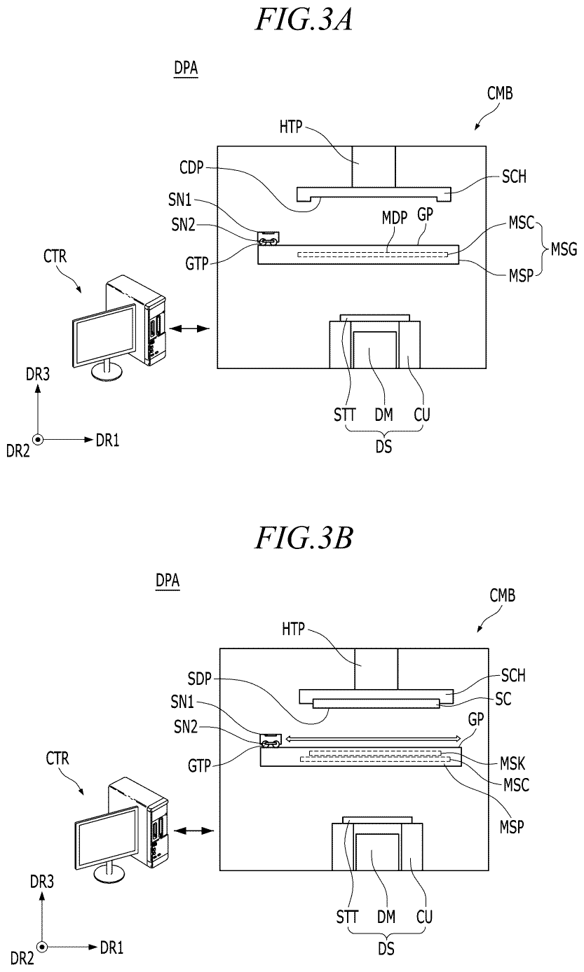

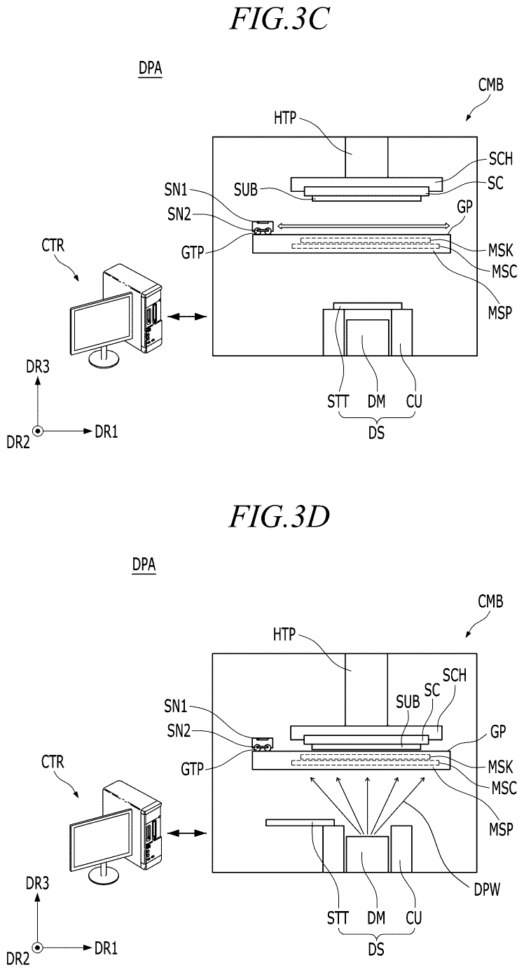

FIG. 2 is an example flow diagram of an operating method S10 of a deposition apparatus according to an embodiment of the disclosure. Each of FIGS. 3A, 3B, 3C, and 3D is a schematic side view of a deposition apparatus in a step of an operation method S10 of a deposition apparatus according to an embodiment of the disclosure.

Referring to FIG. 2, the operating method S10 of a deposition apparatus according to an embodiment of the disclosure may include preparing S100, identifying a mask S200, identifying a substrate chuck S300, disposing a substrate S400, identifying the substrate S500, and deposition S600.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions of “may be disposed,” “may be formed,” “may be measured,” and the like include methods, processes, and techniques for disposing, forming, measuring, and the like in accordance with example aspects described herein.

FIG. 3A may be an illustration of a deposition apparatus DPA before the step S100 of preparing. FIG. 3B may be an illustration of the deposition apparatus DPA after the step S100 of preparing and before performing the step S400 of disposing a substrate. FIG. 3C may be an illustration of the deposition apparatus DPA after the step S400 of disposing a substrate and before performing the step S600 of deposition. FIG. 3D may be an illustration of a deposition apparatus DPA during the step S600 of deposition.

Referring to FIGS. 2 and 3A, there may be no component disposed on the substrate chuck disposition plane CDP and the mask disposition plane MDP in the disposition apparatus DPA before the step S100 of preparing.

Referring to FIGS. 2 and 3B, in the step S100 of preparing, a substrate chuck SC may be disposed on a substrate chuck disposition plane CDP of a substrate chuck holder SCH, and a mask MSK may be disposed on a mask disposition plane MDP of a mask chuck MSC.

The step S200 of identifying a mask may include examining a mask S210, evaluating the mask S220, and adjusting a mask S230 (i.e., solving a problem of a mask S230). In the step S200 of identifying a mask, the operating method S10 may include determining whether there is a problem with a mask MSK, and in a case in which there is a problem with the mask MSK, the problem may be solved.

In the step S210 of examining the mask, flatness of the mask MSK may be measured.

In the step S220 of evaluating the mask, the operating method S10 may include determining whether the flatness of a mask MSK is greater than or equal to a selectable mask reference value and whether the mask MSK is damaged. In a case in which it is determined in the step S220 of evaluating that the flatness of the mask MSK is less than a mask reference value or the mask MSK is identified to be damaged, the step S230 of adjusting the mask may proceed. However, in a case in which it is determined in the step S220 of evaluating the mask that the flatness of a mask is greater than or equal to a mask reference value and the mask MSK is identified to be undamaged, the step S300 of identifying a substrate chuck may proceed.

In the step 230 of adjusting a mask, a mask MSK may be washed or replaced. In another embodiment, in the step 230 of adjusting a mask, a separate device may be operated to increase flatness of a mask MSK. In some aspects, after the step S230 of adjusting a mask, the step S210 of examining a mask and the step S220 of evaluating the mask may be performed again.

The step S300 of identifying a substrate chuck may include examining a substrate chuck S310, evaluating the substrate chuck S320, and adjusting the substrate chuck S330 (i.e., solving a problem of the substrate chuck). In the step S300 of identifying a substrate chuck, the operating method S10 may include determining whether there is a problem with the substrate chuck SC, and in a case in which there is a problem with the substrate chuck SC, the problem may be solved.

In the step S310 of examining the substrate chuck, flatness of the substrate chuck SC may be measured.

In the step S320 of evaluating the substrate chuck, the operating method S10 may include determining whether the flatness of the substrate chuck SC is greater than or equal to a selectable substrate chuck reference value and whether the substrate chuck SC is damaged. In a case in which it is determined in the step S320 of evaluating the substrate chuck that the flatness of the substrate chuck SC is less than a substrate chuck reference value or the substrate chuck SC is damaged, the step S330 of adjusting the substrate chuck may proceed. In another embodiment, in a case in which it is determined in the step S320 of evaluating the substrate chuck that the flatness of the substrate chuck SC is greater than or equal to a selectable substrate chuck reference value and the substrate chuck SC is undamaged, the step S400 of disposing a substrate may proceed.

In the step S330 of adjusting the substrate chuck, the substrate chuck SC may be replaced. In another embodiment, in the step S330 of adjusting a substrate chuck, a separate device may be operated to increase flatness of a substrate chuck SC. In some aspects, after the step S330 of adjusting the substrate chuck, the step S310 of examining the substrate chuck and the step S320 of evaluating the substrate chuck may be performed again.

Referring to FIGS. 2 and 3C, in the step S400 of disposing a substrate, a substrate SUB may be disposed on a substrate disposition plane SDP of the substrate chuck SC. Before the step S400 of disposing a substrate, the step S300 of identifying a substrate chuck may be performed such that a substrate SUB may be disposed on a substrate chuck SC having flatness greater than or equal to a selectable substrate chuck reference value. Accordingly, the substrate SUB may be more stably fixed to the substrate chuck SC.

Identifying a substrate S500 may include examining a substrate S510, evaluating the substrate S520, and solving a problem of the substrate S530. In the step S500 of identifying a substrate, the operating method S10 may include determining whether there is a problem with the substrate SUB, and in a case in which there is a problem with the substrate SUB, the problem may be solved.

In the step S510 of examining a substrate, flatness of the substrate SUB may be measured.

In the step S520 of evaluating the substrate, the operating method S10 may include determining whether the flatness of the substrate SUB is greater than or equal to a selectable substrate reference value and whether the substrate SUB is damaged. In a case in which it is determined in the step S520 of evaluating the substrate that the flatness of the substrate SUB is less than a substrate reference value or the substrate SUB is damaged, the step S530 of solving a problem of the substrate may proceed. In another embodiment, in a case in which it is determined in the step S520 of evaluating the substrate that the flatness of the substrate SUB is greater than or equal to a substrate reference value and the substrate SUB is undamaged, the step S600 of deposition may proceed.

In the step S530 of adjusting the substrate, the substrate SUB may be replaced. In another embodiment, in the step S530 of adjusting the substrate S530, a separate device may be operated to increase flatness of the substrate SUB. In some aspects, after the step S530 of adjusting the substrate S530, the step S510 of examining the substrate and the step S520 of evaluating the substrate may be performed again.

Referring to FIGS. 2 and 3D, in the step S600 of deposition, the crucible CU may be heated and the opening and closing part STT may be open. Accordingly, the vaporized deposition material DM may be released towards above through a deposition path DPW such that a deposition process may be performed on a substrate SUB. In some aspects, the substrate SUB may move in the third direction DR3 via a holder transfer unit HTP such that the step S600 of deposition may be performed while the mask MSK and the substrate SUB are close to each other. Therefore, a deposition layer may be transferred to the substrate SUB according to a shape of a plurality of openings defined in the mask MSK.

Descriptions herein of an operation being performed “while” an element A is in a position with respect to an element B (e.g., while element A and element B are close to each other, while element A overlaps with element B) may refer to a positioning state resulting from movement of one or more of the elements.

In some aspects, as the step S200 of identifying a mask and the step S500 of identifying a substrate may be performed before the step S600 of deposition, flatness of the mask MSK may be greater than equal to a mask reference value and flatness of the substrate SUB may be greater than equal to a substrate reference value. Accordingly, the mask MSK and the substrate SUB may be more stably attached. Therefore, a more uniform deposition layer may be transferred to the substrate SUB according to a shape of a plurality of openings defined in the mask MSK.

However, an operating method of a deposition apparatus is not limited to what is illustrated in the flow diagram of FIG. 2. For example, the step S200 of identifying a mask may be performed after the step S300 of identifying a substrate chuck. In some aspects, the step S200 of identifying a mask may be performed after the step S400 of disposing a substrate. The step S200 of identifying a mask may be irrelevant to an order of other steps if the step S200 of identifying a mask is performed between the step S100 of preparation and the step S600 of deposition.

In some aspects, the step S300 of identifying a substrate chuck may be irrelevant to an order of other steps if the step S300 of identifying a substrate chuck is between the step S100 of preparation and the step S400 of disposing a substrate. The step S500 of identifying a substrate may be irrelevant to an order of other steps if the step S500 of identifying a substrate is between the step S400 of disposing a substrate and the step S600 of deposition.

In some aspects, the step S210 of examining a mask and the step S310 of examining a substrate chuck may be performed simultaneously. In another embodiment, the step S210 of examining a mask and the step S510 of examining a substrate may be performed simultaneously. Accordingly, aspects of the operating method S10 with respect to simultaneous examination may reduce time for measuring the flatness of a substrate chuck SC, a mask MSK, and a substrate SUB with the first measurement unit MP1 and the second measurement unit MP2.

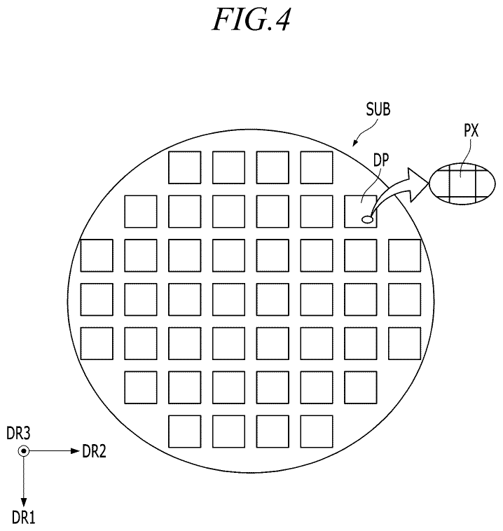

FIG. 4 is an example top view of a substrate SUB according to an embodiment of the disclosure.

Referring to FIG. 4, the substrate SUB may include a plurality of display panels DP. In some aspects, each display panel DP may include a plurality of pixels PX. A substrate SUB may be a subject for which a deposition process is performed with a deposition apparatus DPA illustrated in FIGS. 1A through 1G. The substrate SUB may include a semiconductor wafer. In some aspects, the plurality of display panels DP may be a micro display panel including OLEDoS.

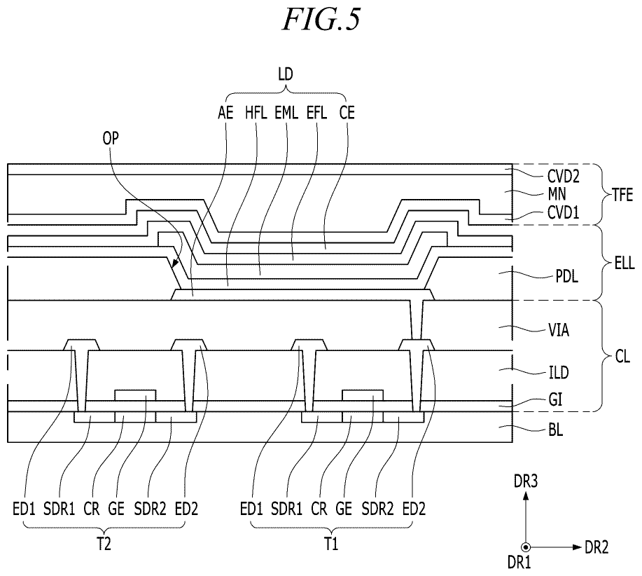

FIG. 5 is an example cross-sectional view of a display panel DP manufactured according to an embodiment of the disclosure.

Referring to FIG. 5, the display panel DP may include a base layer BL, a circuit layer CL, a light-emitting diode layer ELL, and an encapsulation layer TFE. In some aspects, the base layer BL and the circuit layer CL may include a plurality of transistors T1 and T2. Some of the elements of the display panel DP illustrated in FIG. 5 may be elements manufactured through a deposition process with the deposition apparatus DPA illustrated in FIGS. 1A through 1G.

The base layer BL may include a semiconductor wafer. Particularly, the base layer BL may include a silicon wafer, a composition semiconductor wafer, a silicon carbide wafer, a sapphire wafer, or a diamond wafer.

The base layer BL may include a portion of the plurality of transistors T1 and T2. Particularly, the base layer BL may include a plurality of first source drain regions SDR1, a plurality of second source drain regions SDR2, and a plurality of channel regions CR.

The plurality of first source drain regions SDR1 may be formed by doping an impurity on a portion of the base layer. Each of the plurality of first source drain regions SDR1 may include a P-type semiconductor or an N-type semiconductor.

The plurality of second source drain regions SDR2 may be spaced apart from the plurality of first source drain regions SDR1 and formed by doping an impurity to another portion of the base layer BL. Each of the plurality of second source drain regions SDR2 may include a same type of semiconductor as an neighboring first source drain region SDR1. For example, both of the first source drain region SDR1 and the neighboring second source drain region SDR2 may include a P-type semiconductor. Alternatively, both may include an N-type semiconductor.

Each of the plurality of channel regions CR may be formed by doping an impurity to a base layer BL disposed between the first source drain region SDR1 and the neighboring second source drain region SDR2. According to an external condition, each of the plurality of channel regions CR may form a channel through which an electron or a hole may be transported. For example, each of the plurality of channel regions CR may form a channel in a case in which an electric field is applied.

In some aspects, each of the plurality of channel regions CR may include a type of semiconductor which is different from the semiconductor type of an adjacent first source drain region SDR1 and an adjacent second source drain region SDR2. For example, in a case in which both of the adjacent first source drain region SDR1 and the neighboring second source drain region SDR2 may include a P-type semiconductor, each of the plurality of channel regions CR includes an N-type semiconductor. In another embodiment, in a case in which both of the neighboring first source drain region SDR1 and the adjacent second source drain region SDR2 may include an N-type semiconductor, each of the plurality of channel regions CR includes a P-type semiconductor.

The circuit layer CL may include a gate insulating layer GI, an interlayer insulating layer ILD, a circuit insulating layer VIA, and another portion of the plurality of transistors T1 and T2. Particularly, the circuit layer CL may include a control electrode GE, a first electrode ED1, and a second electrode ED2 composing each of the plurality of transistors T1 and T2.

The gate insulating layer GI may cover the base layer BL. The gate insulating layer GI may include an organic film and/or an inorganic film. The gate insulating layer GI may include a plurality of inorganic thin films. The plurality of inorganic thin films may include a silicon nitride layer and a silicon oxide layer.

A plurality of control electrodes GE composing each of the plurality of transistors T1 and T2 may be disposed on the gate insulating layer GI. The plurality of control electrodes GE may overlap with the plurality of channel regions CR. Each of the plurality of control electrodes GE may be applied with voltage such that the plurality of channel regions CR may be applied with an electric field. Accordingly, the plurality of channel regions CR may form a channel. In some aspects, the plurality of control electrodes GE may include molybdenum (Mo).

The interlayer insulating layer ILD may cover the gate insulating layer GI and the plurality of control electrodes GE. The interlayer insulating layer ILD may include an organic film and/or an inorganic film. The interlayer insulating layer ILD may include a plurality of inorganic thin films or organic thin films. The plurality of inorganic thin films may include a silicon nitride layer and a silicon oxide layer.

A plurality of first electrodes ED1 and a plurality of second electrodes ED2 composing each of the plurality of transistors T1 and T2 may be disposed on the interlayer insulating layer ILD. Each of the plurality of first electrodes ED1 may be electrically connected to the plurality of first source drain regions SDR1 through contact holes defined on the interlayer insulating layer ILD. In some aspects, each of the plurality of second electrodes ED2 may be electrically connected to the plurality of second source drain regions SDR2 through contact holes defined on the interlayer insulating layer ILD. The first electrodes ED1 and the second electrodes ED2 may include a metal. In some aspects, the first electrodes ED1 and the second electrodes ED2 may have a multilayer structure. Particularly, each of the first electrodes ED1 and the second electrodes ED2 may be successively laminated with Titanium Ti, Aluminum Al and Titanium Ti.

The circuit insulating layer VIA may cover the interlayer insulating layer ILD, the plurality of first electrodes ED1 and the plurality of second electrodes ED2. The circuit insulating layer VIA may include an organic film and/or an inorganic film. The circuit insulating layer VIA may provide a flat surface. In another embodiment, number of the circuit insulating layer VIA may increase as desired.

The light-emitting diode layer ELL may include a pixel defining film PDL and a light-emitting diode LD.

The pixel defining film PDL may be disposed on a portion of the circuit insulating layer VIA. Accordingly, an opening OP may be defined in another portion where the pixel defining film PDL is not disposed. In some aspects, the light-emitting diode LD may be formed in the opening OP.

The light-emitting diode LD may be configured to emit light. In some aspects, the light-emitting diode LD may include an anode electrode AE, a hole functional layer HFL, a light-emitting layer EML, an electron functional layer EFL, and a cathode electrode CE.

The anode electrode AE may be disposed on a portion of the circuit insulating layer VIA. Particularly, the opening OP may expose the anode electrode. In some aspects, the anode may be electrically connected to the second electrode ED2 through a contact hole defined on the circuit insulating layer VIA. Accordingly, the anode electrode AE may be configured to receive an electrical signal from the first transistor T1 and the second transistor T2.

In FIG. 5, example aspects of the first transistor T1 and the second transistor T2 are illustrated. However, structures of the first transistor T1 and the second transistor T2 are not limited to what is illustrated in the figure. Although it is illustrated in FIG. 5 that the first transistor T1 makes direct contact with the anode electrode AE of the light-emitting diode LD through the second electrode ED2, this is because a cross-sectional shape is illustrated in the figure. The first transistor may be connected to the anode electrode AE of the light-emitting diode LD through another transistor. However, embodiments of the present disclosure are not limited thereto, and in another embodiment, the first transistor T1 may make direct contact with the anode electrode AE of the light-emitting diode LD through the second electrode ED2.

The hole functional layer HFL may be disposed on the anode electrode AE. The hole functional layer HFL may be configured to support transport of a hole generated from the anode electrode AE. For example, the hole functional layer HFL may be configured to more readily receive a hole injected from the anode electrode AE and facilitate transport of the hole. The hole functional layer HFL may have a multilayer structure. For example, the hole functional layer HFL may have a structure further including a hole injection layer (not illustrated) and a hole transfer layer (not illustrated).

The light-emitting layer EML may be disposed on the hole functional layer HFL. The light-emitting layer EML may be configured to emit light. The light-emitting layer EML may include an organic light-emitting material. Therefore, the light-emitting diode LD may be an organic light-emitting diode.

The electron functional layer EFL may be disposed on the light-emitting layer EML. The electron functional layer EFL may be configured to support transport of an electron generated from the cathode electrode CE. For example, the electron functional layer EFL may be configured to more readily receive an electron injected from the cathode electrode CE and facilitate transport of the electron. The electron functional layer EFL may have a multi-layer structure. For example, the electron functional layer EFL may have a structure further including an electron injection layer (not illustrated) and an electron transport layer (not illustrated).

The cathode electrode CE may be disposed on the electron functional layer EFL. The cathode electrode CE may have a low resistance such that flow electric current is facilitated.

The encapsulation layer TFE may be configured to seal off the light-emitting diode LD to protect the light-emitting diode LD from external oxygen or moisture. The encapsulation layer TFE may include a first encapsulation inorganic layer CVD1, an encapsulation organic layer MN, and a second encapsulation inorganic layer CVD2.

In FIG. 5, the encapsulation layer TFE is illustrated, as an example, to include two inorganic layers CVD1 and CVD2 and one encapsulation organic layer MN, but embodiments of the present disclosure are not limited thereto. For example, the encapsulation layer TFE may include three encapsulation inorganic layers and two encapsulation organic layers, and in this case, the inorganic layers and the organic layers may be alternately laminated.

The deposition apparatus DPA of the disclosure may be used for formation of at least one of a gate insulating layer GI, an interlayer insulating layer ILD, a circuit insulating layer VIA, a light-emitting layer EML or an encapsulation organic layer MN including an organic material. However, an element which may be formed with the deposition apparatus DPA of the disclosure is not limited to the above examples. An element composing a display panel DP which may be formed through a deposition process may be formed with the deposition apparatus DPA of the disclosure.

Subsequently, another embodiment of the disclosure is more specifically described by referring to the figure.

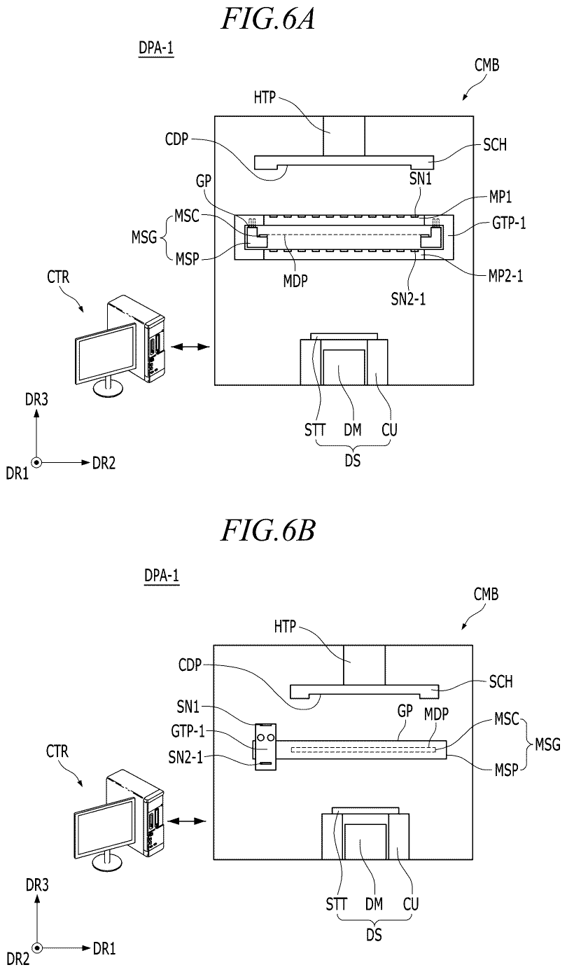

FIG. 6A is an example front view of a deposition apparatus DPA-1 according to an embodiment of the disclosure. FIG. 6B is an example side view of a deposition apparatus DPA-1 according to an embodiment of the disclosure.

Referring to FIGS. 6A and 6B, a portion of the guide transfer unit GTP-1 may extend in the third direction DR3. In some aspects, the second measurement unit MP2-1 may be disposed on an extended point of the guide transfer unit GTP-1 in the third direction DR3. Accordingly, the second measurement unit MP2-1 may be disposed below the mask chuck MSC. In some aspects, the second measurement unit MP2-1 and a second sensor SN2-1 may face above. Accordingly, the second measurement unit MP2-1 may face a bottom surface of a mask MSK.

In some aspects, the second measurement unit MP2-1 may be configured to measure an amount of a deposition material deposited at the bottom surface of the mask MSK. For example, a separate sensor configured to measure an amount of a deposition material deposited on the mask MSK may be disposed on the second measurement unit MP2-1 such that an amount of a deposition material deposited at the bottom of the mask MSK is measured.

Furthermore, in a case in which an amount of a deposition material deposited on the mask MSK is greater than or equal to a selectable deposition amount reference value, the controller CTR may have the mask MSK washed or replaced. Therefore, a washing period of a replacement period of a mask MSK may be controlled based on an amount of a deposition material deposited on the mask MSK. Accordingly, embodiments of the present disclosure support reducing costs incurred in a case in which a washing period or a replacement period of a mask MSK is too short. In some aspects, embodiments of the present disclosure support preventing a performance problem of a mask MSK occurring in a case in which a washing period or a replacement period of a mask MSK is too long.

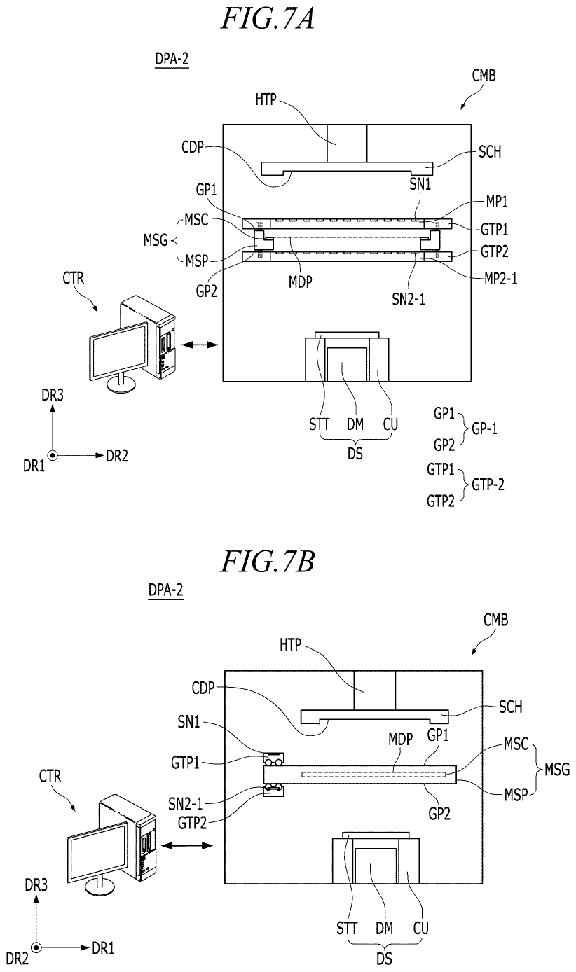

FIG. 7A is an example front view of a deposition apparatus DPA-2 according to an embodiment of the disclosure. FIG. 7B is an example side view of a deposition apparatus DPA-2 according to an embodiment of the disclosure.

Referring to FIGS. 7A and 7B, the guide GP-1 may include a first guide GP1 and a second guide GP2. A guide transfer unit GTP-2 may include a first guide transfer part GTP1 and a second guide transfer part GTP2.

The first guide GP1 and the second guide GP2 may be spaced apart from each other.

The first guide transfer unit GTP1 may be disposed on the first guide GP1. The second guide transfer unit GTP2 may be disposed on the second guide GP2 and spaced apart from the first guide transfer unit GTP1.

The first measurement unit MP1 may make contact with the first guide transfer unit GTP1, and the second measurement unit MP2-1 may make contact with the second guide transfer unit GTP2. Accordingly, the first measurement unit MP1 and the second measurement unit MP2-1 may move independently such that the flatness of a first measurement subject and a second measurement subject may be measured more freely.

There may be two first measurement subjects, which are a substrate chuck SC and a substrate SUB, while there may be one second measurement subject, which is a mask MSK. Accordingly, the first guide transfer unit GTP1 may be set to have a high speed. The second guide transfer unit GTP2 may be set to have a slow speed.

Accordingly, the first measurement unit MP1 may be configured to more quickly measure flatness of the first measurement subject such that a deposition process may be performed more frequently. In some aspects, the second measurement unit MP2-1 may be configured to more slowly and more precisely measure flatness of the second measurement subject such that the flatness of the mask MSK and an amount of a deposition material deposited on the mask MSK is accurately determined and a deposition process is more precisely performed.

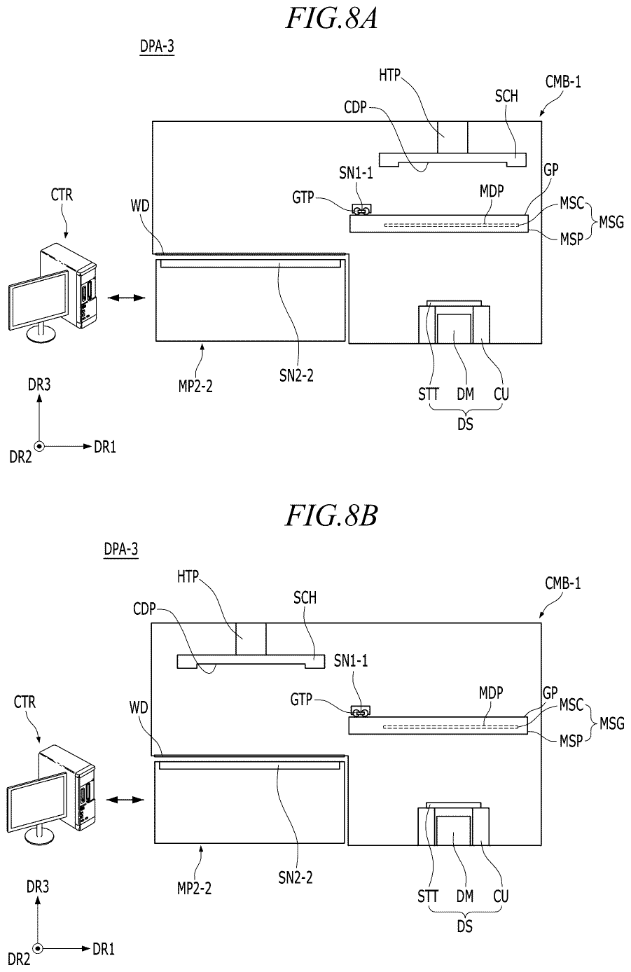

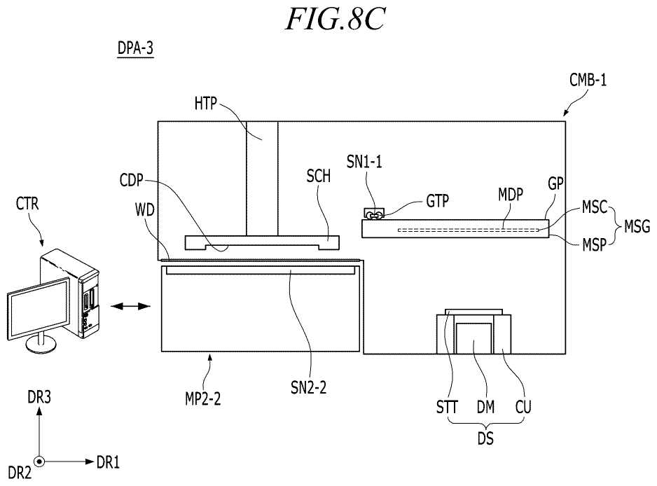

FIGS. 8A, 8B, and 8C are example side views of a deposition apparatus DPA-3 according to an embodiment of the disclosure.

Referring to FIGS. 8A, 8B, and 8C, the chamber CMB-1 may include a transparent member WD overlapping with the second measurement unit MP2-2. The chamber CMB-1 may be configured to accommodate a holder transfer unit HTP, a substrate chuck holder SCH, a mask stage MSG, a guide GP, a guide transfer unit GTP, a first measurement unit MP1, and a deposition source DS.

A first sensor SN1-1 may face downwards. Therefore, the first measurement unit MP1 may face the mask MSK. Accordingly, the mask MSK may be defined as a first measurement subject.

The second measurement unit MP2-2 may include a second sensor SN2-2. In some aspects, the second measurement unit MP2-2 may be disposed outside of the chamber CMB-1. The second measurement unit MP2-2 may be configured to measure flatness of a second measurement subject disposed on an opposite side of the transparent member WD through the transparent member WD. For example, the substrate chuck holder SCH may be moved by the holder transfer unit HTP as illustrated in FIG. 8B. In some aspects, the second measurement unit MP2-2 may face a substrate chuck SC disposed on the substrate chuck holder SCH and a substrate SUB disposed the substrate chuck SC. Accordingly, the substrate chuck SC and the substrate SUB may be defined as the second measurement subject.

In some aspects, in a case in which the substrate chuck holder SCH is moved by the holder transfer unit HTP in the third direction DR3 as illustrated in FIG. 8C, a distance between the second measurement unit MP2-2 and the second measurement subject may be adjusted. Accordingly, embodiments of the present disclosure support obtaining a more accurate value of flatness of the substrate chuck SC and the substrate SUB measured with the second measurement unit MP2-2.

The second sensor SN2-2 may be a non-contact surface measurement sensor facing above. The second sensor SN2-2 may be configured to identify a shape of a surface positioned above. The second sensor SN2-2 may identify a surface of the second measurement subject such that the flatness of the second measurement subject is measured.

The second sensor SN2-2 may include at least one of a laser Fizeau interferometer, a phase measuring deflectometry, a multi-beam optical sensor, or a flying spot scanner. However, an element of the second sensor SN2-2 is not limited to the above examples. Any sensor configured to identify a shape of a surface other than the examples may be included in the second sensor SN2-2.

The second sensor SN2-2 may be disposed outside of the chamber CMB-1 such that the second sensor is not exposed to a vacuum environment and a deposition material inside the chamber CMB-1. Therefore, a device, which is difficult to be used under a vacuum environment, may be used as the second sensor SN2-2. In some aspects, a lifespan of the second sensor SN2-2 may be increased.

An element of the second measurement is not limited to the above examples. The second sensor SN2-2 may include a non-contact displacement sensor. In some aspects, the second measurement unit MP2-2 may include a separate element configured to move the second sensor SN2-2. In some aspects, the second sensor SN2-2 may be configured to scan the second measurement subject to measure flatness of the second measurement subject.

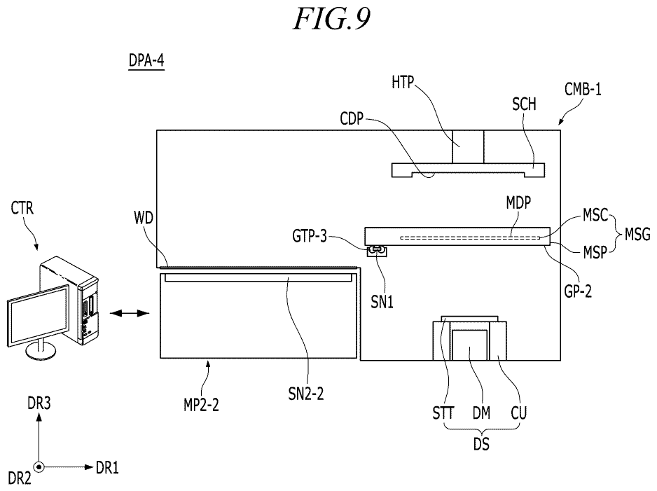

FIG. 9 is an example side view of a deposition apparatus DPA-4 according to an embodiment of the disclosure.

Referring to FIG. 9, the guide GP-2 may be disposed below the mask support MSP. In some aspects, the guide transfer unit GTP-3 may make contact with the guide GP-2. The first sensor SN1 may face above.

Accordingly, in FIG. 9, the first measurement unit MP1 may face a bottom surface of the mask MSK disposed on the mask disposition plane MDP. The first measurement unit MP1 may be configured to measure an amount of a deposition material deposited on the mask MSK.

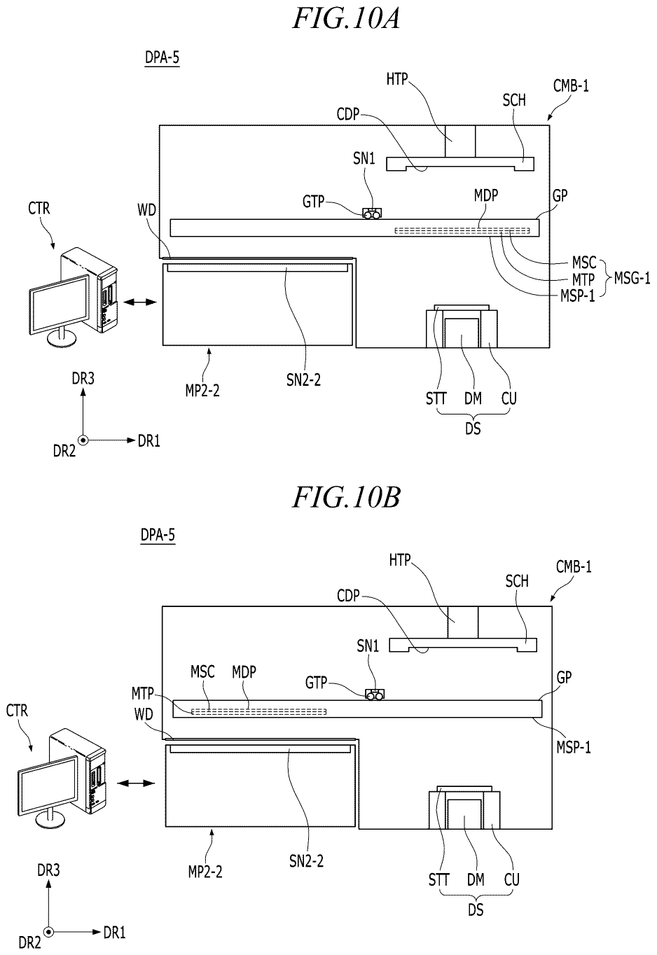

FIGS. 10A and 10B are example side views of a deposition apparatus DPA-5 according to an embodiment of the disclosure.

Referring to FIGS. 10A and 10B, the mask stage MSG-1 may further include a mask transfer unit MTP. In some aspects, the mask support MSP-1 may further extend in the first direction DR1.

The mask transfer unit MTP may be disposed on a mask support MSP-1. In some aspects, a mask chuck MSC may be disposed on the mask transfer unit MTP. The mask transfer unit MTP may move along with the mask support MSP-1 in the first direction DR1. The mask chuck MSC may be moved by the mask transfer unit MTP in the first direction DR1.

The mask chuck MSC may move in the first direction DR1 to overlap with the second measurement MP2-2 as illustrated in FIG. 10B. Accordingly, the second measurement unit MP2-2 may face the mask MSK. As a result, the mask MSK may be defined as a second measurement subject.

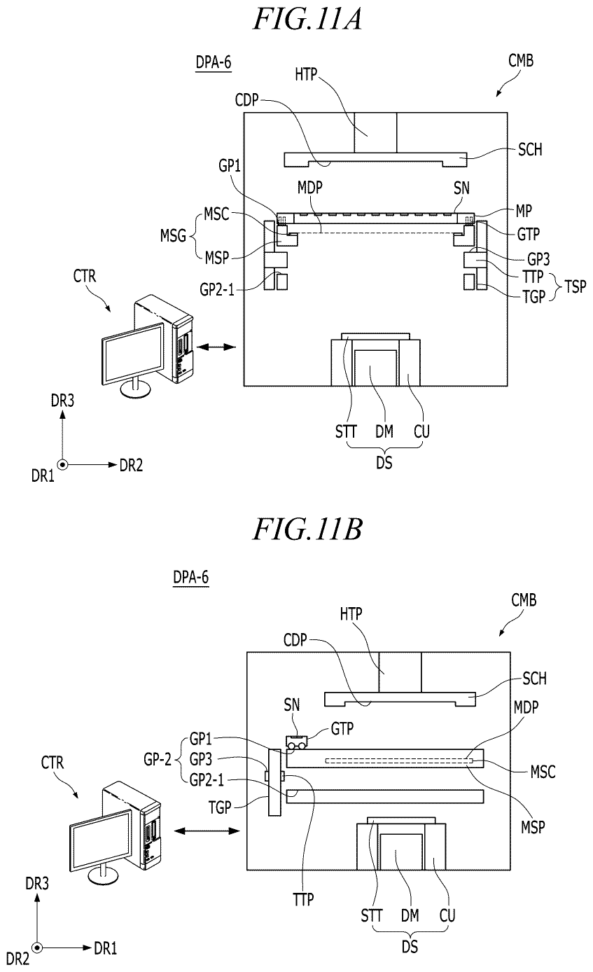

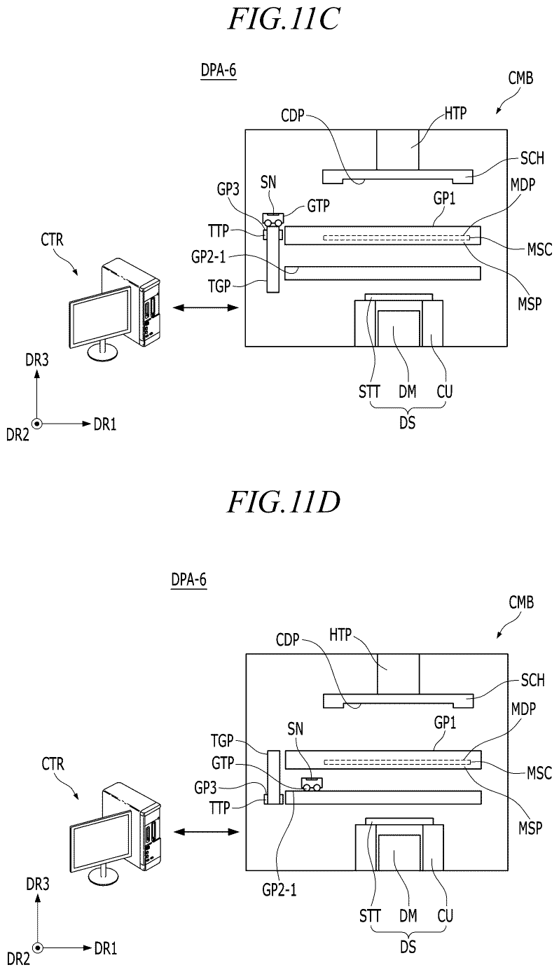

FIG. 11A is an example front view of a deposition apparatus DPA-6 according to an embodiment of the disclosure. FIGS. 11B, 11C, and 11D are example side views of a deposition apparatus DPA-6 according to an embodiment of the disclosure.

Referring to FIGS. 11A and 11B, the deposition apparatus DPA-6 may include one measurement unit MP instead of a first measurement unit MP1 and a second measurement unit MP2. In some aspects, the deposition apparatus DPA-6 may further include a mode switch unit TSP. The guide GP-2 may include a first guide GP1, a second guide GP2-1, and a third guide GP3.

The measurement unit MP may include a sensor SN. The measurement unit MP may be substantially the same as one of the first measurement unit MP1 or the second measurement unit MP2. In some aspects, the subject of which flatness is measured by the measurement unit MP may be defined as a measurement subject.

The measurement unit MP may have an upper mode or a lower mode. For example, the measurement unit MP may operate according to the upper mode or the lower mode. The measurement unit MP may be configured to measure flatness of at least one of a substrate chuck SC or a substrate SUB under the upper mode, and flatness of a mask MSK under the lower mode. For example, a substrate chuck SC, a substrate SUB, and a mask MSK may be defined as a measurement subject.

The sensor SN may be the same as the first sensor SN1 and the second sensor SN2. However, unlike the first sensor SN1 and the second sensor SN2, the sensor SN may be positioned at a first height or a second height. In a case in which the sensor SN is positioned at the first height, the measurement unit MP may be set as the upper mode. In a case in which the sensor SN is positioned at the second height, the measurement unit MP may be set as the lower mode.

Particularly, the first height may be higher than a height where a mask chuck MSC is positioned and lower than a height where a substrate chuck holder SCH is positioned. In some aspects, the second height may be lower than a height where the mask chuck MSC is positioned. Furthermore, as the measurement unit MP and the sensor SN face above, in a case in which the sensor SN is positioned at the first height, the measurement unit MP may measure flatness of at least one of the substrate chuck SC or the substrate SUB. In some aspects, in a case in which the sensor SN is positioned at the second height, the measurement unit MP may measure flatness of the mask MSK.

The mode switch unit TSP may include a switch guide TGP and a switch transfer unit TTP. The mode switch unit TSP may switch a mode of the measurement unit MP to the upper mode or the lower mode. For example, the mode switch unit TSP may be configured to adjust a height of the sensor SN.

The switch guide TGP may extend in the third direction. The switch guide TGP may include a linear motion guide. However, an element of the switch guide TGP is not limited to the above. The switch guide TGP may have the same configuration as the guide GP.

The switch transfer unit TTP may include a linear motion block disposed on the switch guide TGP. Accordingly, the switch transfer unit TTP may move along with the switch guide TGP. However, an element of the switch transfer unit TTP is not limited to the above. The switch transfer unit TTP may have the same configuration as the guide transfer unit GTP.

The guide GP-2 may include a first guide GP1, a second guide GP2-1, and a third guide GP3. The first guide GP1 may be disposed on a mask support MSP. The second guide GP2-1 may be disposed on a separate member positioned below the first guide GP1. The third guide GP3 may be disposed on the switch transfer unit TTP.

Referring to FIGS. 11C and 11D, the third guide GP3 may be positioned on extension of the first guide GP1 or on extension of the second guide GP2-1 according to a position of the switch transfer unit TTP.

Therefore, in a case in which the switch transfer unit TTP moves above and the third guide GP3 is positioned on the extension of the first guide GP1, the measurement unit MP positioned on the first guide GP1 may move to the third guide GP3 as illustrated in FIG. 11C.

In some aspects, the switch transfer unit TTP may move below such that the third guide GP3 is positioned on extension of the second guide GP2-1. Accordingly, the measurement unit MP positioned on the third guide GP3 may move to the second guide GP2-1 as illustrated in FIG. 11D.

In a case in which the guide transfer unit GTP is positioned on the first guide GP1, the measurement unit MP may be under the upper mode. In some aspects, in a case in which the guide transfer unit GTP is positioned on the second guide GP2-1, the measurement unit MP may be under the lower mode. Therefore, the height of the sensor SN may be adjusted, and a mode of the measurement unit MP may be switched by the mode switch unit TSP.

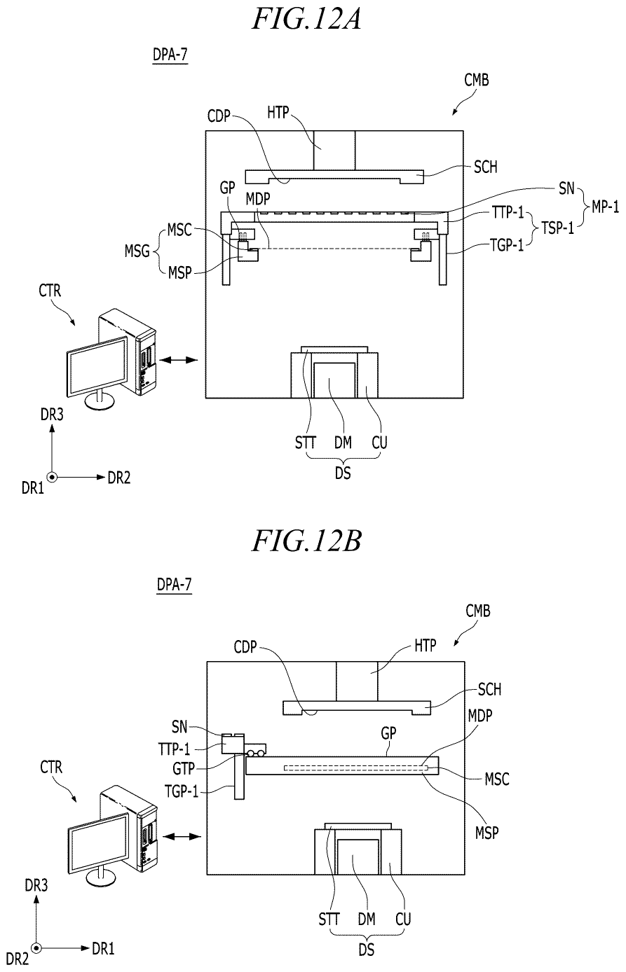

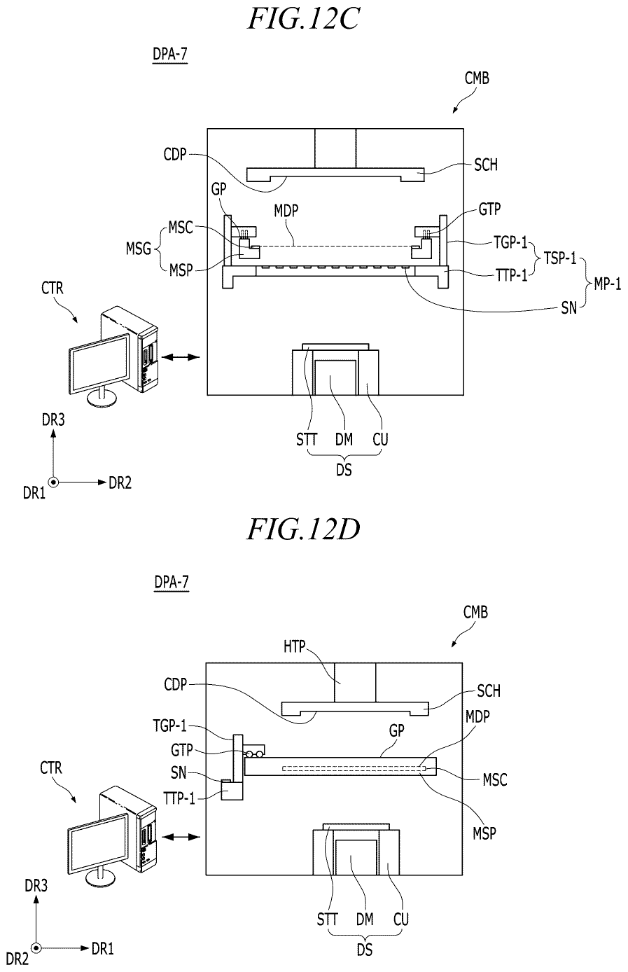

FIGS. 12A and 12C are examples front views of a deposition apparatus DPA-7 according to an embodiment of the disclosure. FIGS. 12B and 12D are example side views of a deposition apparatus DPA-7 according to an embodiment of the disclosure.

Referring to FIGS. 12A and 12B, the measurement unit MP-1 may further include a mode switch unit TSP-1. The mode switch unit TSP-1 may switch a mode of the measurement unit MP-1 to an upper mode or a lower mode. For example, the mode switch unit TSP-1 may adjust a height of a sensor SN.

In FIGS. 12A and 12B, the measurement unit MP-1 may be under the upper mode. Accordingly, in FIGS. 12A and 12B, the sensor SN may be positioned at a first height. The first height may be higher than a position of a mask chuck MSC and lower than a position of a substrate chuck holder SCH.

A switch guide TGP-1 may make contact with a guide transfer unit GTP. In some aspects, the switch guide TGP-1 may extend in the third direction DR3. The switch guide TGP-1 may include a linear motion guide.

A switch transfer unit TTP-1 may include a linear motion block disposed on the switch guide TGP-1. Accordingly, the switch transfer unit TTP-1 may move along with the switch guide TGP-1.

Referring to FIGS. 12C and 12D, the measurement unit MP-1 may be under the lower mode. Therefore, the sensor SN may be positioned at a second height as illustrated in FIGS. 12C and 12D. In some aspects, the second height may be lower than a height where the mask chuck MSC is positioned.

Referring to FIGS. 12A through 12D, a height of the sensor SN may be adjusted by the mode switch unit TSP-1. As a result, a mode of the measurement unit MP-1 may be changed to the upper mode or the lower mode by the mode switch unit TSP-1.

The switch transfer unit TTP-1 may continuously move in the third direction DR3. Therefore, the first height and the second height may be adjusted according to a setting without modification of a configuration. Accordingly, a distance between the sensor SN and the measurement subject may be adjusted to more accurately measure flatness of the measurement subject with the measurement unit MP-1.

Particularly, in a case in which a distance between the sensor SN and the measurement subject is within a selectable range based on a configuration of the sensor SN, a measured value of flatness of the measurement subject with the measurement unit MP-1 may become more accurate. Accordingly, the first height and the second height may be adjusted by the switch transfer unit TTP-1 such that the flatness of the measurement subject is more accurately measured with the measurement unit MP-1.

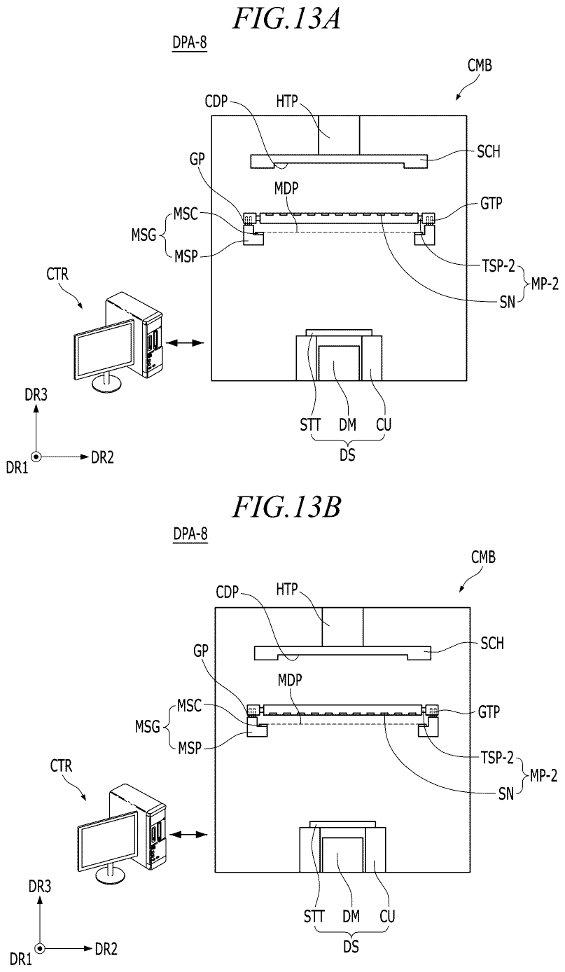

FIGS. 13A and 13B are example front views of a deposition apparatus DPA-8 according to an embodiment of the disclosure.

Referring to FIGS. 13A and 13B, the measurement unit MP-2 may further include a mode switch unit TSP-2. The mode switch unit TSP-2 may change a mode of the measurement unit MP-2 to an upper mode or a lower mode. The mode switch unit TSP-2 may adjust a height of the sensor SN and a direction towards which the sensor SN faces.

The mode switch unit TSP-2 may make contact with the guide transfer unit GTP. In some aspects, the mode switch unit TSP-2 may rotate about the second directional axis DR2. Accordingly, the mode switch unit TSP-2 may adjust a height of the sensor SN and a direction towards which the sensor SN faces.

In FIG. 13A, the measurement unit MP-2 may be set under the upper mode. In a case in which the measurement unit MP-2 is set under the upper mode, the sensor SN may be positioned at a first height. The first height may be higher than a position of the mask chuck MSC and lower than a position of the substrate chuck holder SCH. In some aspects, under the upper mode, the sensor SN may face above.

In FIG. 13B, the measurement unit MP-2 may be set under the lower mode. In a case in which the measurement unit MP-2 is set under the lower mode, the sensor SN may be positioned at a second height. The second height may be higher than a position of the mask chuck MSC, lower than the substrate chuck holder SCH, and lower than the first height. In some aspects, under the lower mode, the sensor SN may face downward.

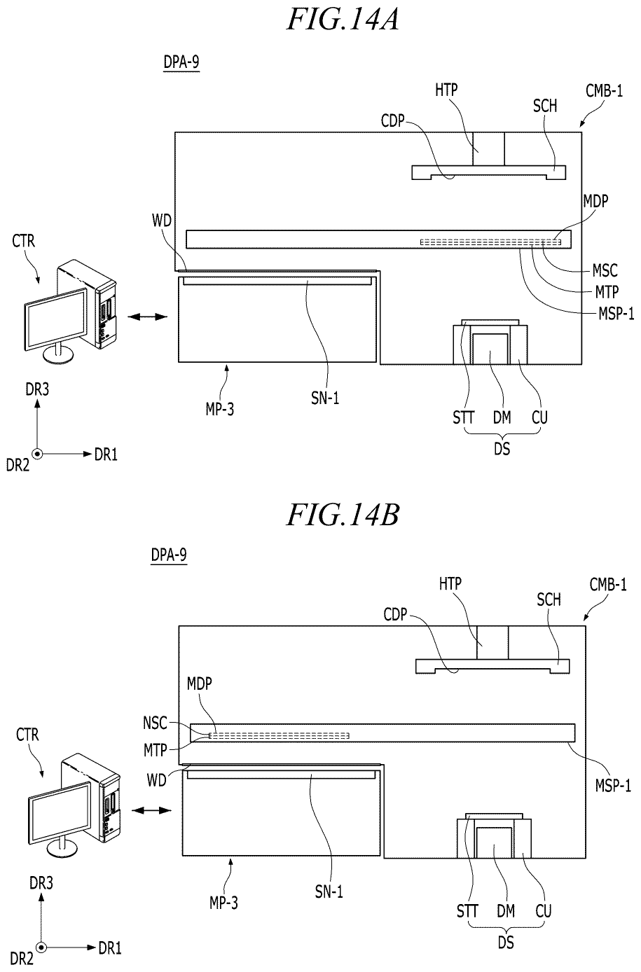

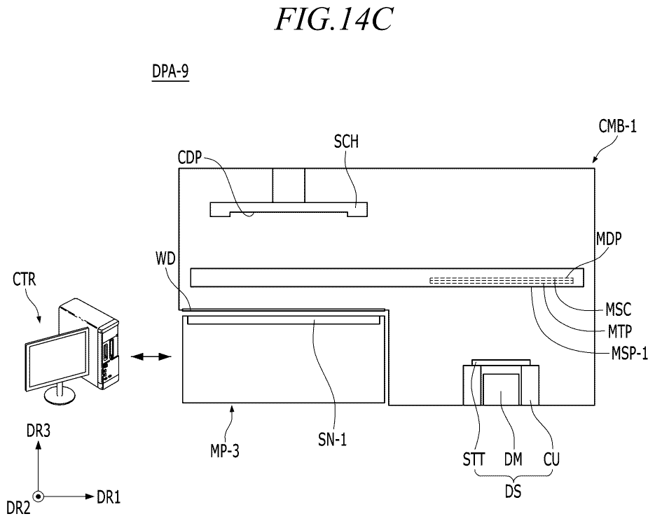

FIGS. 14A, 14B, and 14C are example side views of a deposition apparatus DPA-9 according to an embodiment of the disclosure.

Referring to FIG. 14A, the chamber CMB-1 may include a transparent member WD overlapping with the measurement unit MP-3. The chamber CMB-1 may be configured to accommodate a holder transfer unit HTP, a substrate chuck holder SCH, a mask stage MSG-1, a guide GP, a guide transfer unit GTP, and a deposition source DS.

The measurement unit MP-3 may be the same as the measurement unit MP2-2 illustrated in FIGS. 8A, 8B, 8C, 9, 10A, and 10B. The mask stage MSG-1 may be the same as the mask stage MSG-1 illustrated in FIGS. 10A and 10B. The deposition apparatus DPA-9 may include both of the holder transfer unit HTP and the mask transfer unit MTP.

In FIG. 14B, the mask chuck MSC may be moved by the mask transfer unit MTP in the first direction DR1. Accordingly, the mask chuck MSC may overlap with the measurement unit MP-3. Therefore, flatness of the mask MSK may be measured with the measurement unit MP-3.

In FIG. 14C, the substrate chuck holder SCH may be moved by the holder transfer unit HTP. In some aspects, the measurement unit MP-3 may face the substrate chuck holder SCH. Furthermore, flatness of the substrate chuck SC and the substrate SUB may be measured with the measurement unit MP-3.

Accordingly, flatness of the substrate chuck SC, the mask MSK, and the substrate SUB may be measured with the measurement unit MP-3 in FIGS. 14A through 14C.

While certain embodiments of the disclosure have been described herein, anyone ordinarily skilled in the art to which the disclosure pertains shall appreciate that there may be a variety of modifications and permutations of the disclosure without departing from the technical ideas and scopes of the disclosure that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A deposition apparatus comprising:
a substrate chuck holder on which a substrate chuck which fixes a substrate is disposed;
a mask chuck which fixes a mask defined with a plurality of openings and is spaced apart from the substrate chuck holder;
a guide which extends in a first direction parallel to a plane of the substrate chuck holder;
a guide transfer unit which is disposed on the guide and moves along with the guide in the first direction;
a first measurement unit which makes contact with the guide transfer unit, extends in a second direction intersecting with the first direction, and comprises a first sensor; and
a second measurement unit comprising a second sensor spaced apart from the first sensor,
wherein:
in a case in which the first measurement unit measures flatness of at least one of the substrate chuck or the substrate, the second measurement unit measures flatness of the mask, and
in a case in which the first measurement unit measures the flatness of the mask, the second measurement unit measures the flatness of at least one of the substrate chuck or the substrate.

2. The deposition apparatus of claim 1, wherein the second measurement unit makes contact with the guide transfer unit and extends in the second direction.

3. The deposition apparatus of claim 2, wherein the deposition apparatus:
simultaneously measures flatness of the substrate chuck and flatness of the mask, or
simultaneously measures flatness of the substrate and flatness of the mask.

4. The deposition apparatus of claim 2, wherein the first measurement unit overlaps with the second measurement unit in a third direction orthogonal to the first direction and the second direction.

5. The deposition apparatus of claim 4, wherein:
the substrate chuck holder is disposed above the first measurement unit,
the mask chuck is disposed below the second measurement unit,
the first measurement unit measures the flatness of at least one of the substrate chuck or the substrate, and
the second measurement unit measures the flatness of the mask.

6. The deposition apparatus of claim 4, wherein:
the substrate chuck holder is disposed above the first measurement unit,
the mask chuck is disposed above the second measurement unit,
the first measurement unit measures the flatness of at least one of the substrate chuck or the substrate, and
the second measurement unit measures the flatness of the mask.

7. The deposition apparatus of claim 1, wherein:
the guide comprises a first guide and a second guide spaced apart from the first guide,
the guide transfer unit comprises a first guide transfer unit disposed on the first guide and a second guide transfer unit spaced apart from the first guide transfer unit and disposed on the second guide,
the first measurement unit makes contact with the first guide transfer unit,
the second measurement unit makes contact with the second guide transfer unit and extends in the second direction,
the substrate chuck holder is disposed above the first measurement unit,
the mask chuck is disposed below the second measurement unit,
the first measurement unit measures the flatness of at least one of the substrate chuck or the substrate, and
the second measurement unit measures the flatness of the mask.

8. The deposition apparatus of claim 1, wherein:
the first measurement unit measures the flatness of the mask,
the second measurement unit measures the flatness of at least one of the substrate chuck or the substrate,
the substrate chuck holder moves in a direction parallel to a plane defined by the first direction and the second direction, and
while the second measurement unit measures the flatness of at least one of the substrate chuck or the substrate, the second measurement unit does not overlap with the mask chuck in a third direction orthogonal to the first direction and the second direction.

9. The deposition apparatus of claim 8, further comprising a chamber comprising a transparent member overlapping with the second measurement unit in the third direction, wherein:
the chamber accommodates the substrate chuck holder, the mask chuck, the guide, the guide transfer unit and the first measurement unit inside the chamber, and
the second measurement unit is disposed outside of the chamber.

10. The deposition apparatus of claim 1, wherein:
the first measurement unit measures the flatness of at least one of the substrate chuck or the substrate,
the second measurement unit measures the flatness of the mask,
the mask chuck moves in a direction parallel to a plane defined by the first direction and the second direction, and
while the second measurement unit measures the flatness of the mask, the second measurement unit does not overlap with the substrate chuck holder in a third direction orthogonal to the first direction and the second direction.

11. The deposition apparatus of claim 10, further comprising a chamber comprising a transparent member overlapping with the second measurement unit in the third direction, wherein:
the chamber accommodates the substrate chuck holder, the mask, the guide, the guide transfer unit, and the first measurement unit inside the chamber, and
the second measurement unit is disposed outside of the chamber.

12. The deposition apparatus of claim 1, further comprising a controller, wherein:
the controller controls the substrate chuck to fix the substrate in a case in which the flatness of the substrate chuck is greater than or equal to a selectable substrate chuck reference value, and
the controller proceeds with controlling a deposition process in a case in which the flatness of the mask is greater than or equal to a selectable mask reference value and the flatness of the substrate is greater than or equal to a selectable substrate reference value.

13. The deposition apparatus of claim 12, wherein the controller is configured to control the substrate chuck to fix the substrate in a case in which the flatness of the substrate chuck is greater than or equal to a selectable substrate chuck reference value and the flatness of the mask is greater than or equal to a selectable mask reference value.

14. A deposition apparatus comprising:
a substrate chuck holder on which a substrate chuck which fixes a substrate is disposed;
a mask chuck which fixes a mask defined with a plurality of openings and is spaced apart from the substrate chuck holder;
a guide which extends in a first direction parallel to a plane of the substrate chuck holder;
a guide transfer unit which is disposed on the guide and moves along with the guide in the first direction; and
a measurement unit which makes contact with the guide transfer unit, extends in a second direction intersecting with the first direction, comprises a sensor,
wherein:
the measurement unit has an upper mode, in which the sensor is positioned at a first height, and a lower mode, in which the sensor is positioned at a second height lower than the first height,
the measurement unit is measures flatness of at least one of the substrate chuck or the substrate under the upper mode, and
the measurement unit measures flatness of the mask under the lower mode.

15. The deposition apparatus of claim 14, wherein:
the substrate chuck holder is disposed at a position higher than the first height, and
the mask chuck is disposed at a position lower than the second height.

16. The deposition apparatus of claim 14, wherein:
the substrate chuck holder is disposed at a position higher than the first height, and
the mask chuck is disposed at a position lower than the first height and higher than the second height.

17. The deposition apparatus of claim 16, wherein:
the guide comprises a first guide and a second guide disposed at a position lower than the first guide,
the measurement unit makes contact with the first guide under the upper mode, and
the measurement unit makes contact with the second guide under the lower mode.

18. The deposition apparatus of claim 14, further comprising a controller, wherein:
the controller controls the substrate chuck to fix the substrate in a case in which the flatness of the substrate chuck is greater than or equal to a selectable substrate chuck reference value, and
the controller proceeds with controlling a deposition process in a case in which the flatness of the mask is greater than or equal to a selectable mask reference value and the flatness of the substrate is greater than or equal to a selectable substrate reference value.

19. A deposition apparatus comprising:
a substrate chuck holder on which a substrate chuck which fixes a substrate is disposed;
a mask chuck which fixes a mask defined with a plurality of openings and is spaced apart from the substrate chuck holder;
a chamber comprising a transparent member which accommodates the substrate chuck holder and the mask chuck inside of the chamber; and
a measurement unit which comprises a sensor, overlaps with the transparent member, and is disposed outside of the chamber,
wherein:
the substrate chuck holder and the mask chuck move in a direction parallel to a plane on which the substrate chuck is disposed,
the measurement unit measures flatness at least one of the substrate chuck or the substrate while the measurement unit overlaps with the substrate chuck holder and not with the mask chuck, and
the measurement unit measures flatness of the mask while the measurement unit overlaps with the mask chuck.

20. The deposition apparatus of claim 19, further comprising a controller, wherein:
the controller controls the substrate chuck to fix the substrate in a case in which the flatness of the substrate chuck is greater than or equal to a selectable substrate chuck reference value, and
the controller proceeds with controlling a deposition process in a case in which the flatness of the mask is greater than or equal to a selectable mask reference value and the flatness of the substrate is greater than or equal to a selectable substrate reference value.
